(19) United States
(12) Patent Application Publication
(10) Pub. No.: US 2019/0371226 A1
(43) Pub. Date: Dec. 5, 2019

(54) SEMICONDUCTOR DEVICE AND DISPLAY SYSTEM

(71) Applicant: Semiconductor Energy Laboratory Co., Ltd., Atsugi-shi, Kanagawa-ken (JP)

(72) Inventor: Yuji IWAKI, Isehara (JP)

(21) Appl. No.: 16/480,078

(22) PCT Filed: Feb. 5, 2018
(86) PCT No.: PCT/IB2018/050692

§ 371 Date: Jul. 23, 2019

(30) Foreign Application Priority Data
Feb. 15, 2017 (JP) 2017-025614

(51) Int. Cl. G09G 3/20; G06N 3/04; G06N 3/08; G11C 11/401; G09G 3/36; G11C 7/10; H01L 27/12; H01L 29/786; G11C 11/54; H01L 21/8258; H01L 27/088; H01L 27/32

(52) U.S. Cl. CPC G09G 3/2085; G09G 2310/0264; G06N 3/084; G11C 11/401; G09G 3/36; G11C 7/1006; H01L 27/1207; H01L 27/1225; H01L 29/78648; G11C 11/54; H01L 21/8258; H01L 27/088; H01L 27/3244; G09G 2300/0426; G09G 2310/0221; G06N 3/0454

(57) ABSTRACT

A novel semiconductor device or display system is provided. A pixel portion is divided into a plurality of regions, and correction in gray level utilizing artificial intelligence is performed in each of the regions. Specifically, learning of an artificial neural network is performed using data corresponding to an image that is actually displayed on a display portion and data corresponding to an ideal image that is intended to be displayed on the display portion as learning data and teacher data, respectively. Then, based on the result of the learning, the gray levels of pixels are corrected in each divided region, whereby a variation in gray level is compensated. Thus, display of a high-quality image becomes possible.

### TECHNICAL FIELD

One embodiment of the present invention relates to a semiconductor device and a display system.

Note that one embodiment of the present invention is not limited to the above technical field. Examples of the technical field of one embodiment of the present invention disclosed in this specification and the like include a semiconductor device, a display device, an arithmetic device, a light-emitting device, a power storage device, a memory device, a display system, an electronic device, a lighting device, an input device, an input/output device, a driving method thereof, and a manufacturing method thereof.

In this specification and the like, a semiconductor device generally means a device that can function by utilizing semiconductor characteristics. A transistor, a semiconductor circuit, an arithmetic device, a memory device, and the like are each an embodiment of the semiconductor device. In addition, a display device, an imaging device, an electro-optical device, a power generation device (e.g., a thin film solar cell and an organic thin film solar cell), and an electronic device may each include a semiconductor device.

### BACKGROUND ART

Flat panel displays typified by liquid crystal display devices and light-emitting display devices are widely used for displaying images. Although the transistors used in these display devices are mainly manufactured using silicon semiconductors, attention has been drawn to a technique in which a metal oxide exhibiting semiconductor characteristics is used for transistors instead of a silicon semiconductor in recent years. For example, in Patent Documents 1 and 2, a technique is disclosed in which a transistor manufactured using zinc oxide or an In—Ga—Zn-based oxide as a semiconductor layer is used in a pixel of a display device.

### REFERENCE

### Patent Document

[Patent Document 1] Japanese Published Patent Application No. 2007-96055

[Patent Document 2] Japanese Published Patent Application No. 2007-123861

### DISCLOSURE OF INVENTION

An object of one embodiment of the present invention is to provide a novel semiconductor device or display system. Another object of one embodiment of the present invention is to provide a semiconductor device or display system enabling display of high-quality images. Another object of one embodiment of the present invention is to provide a semiconductor device or display system enabling a display portion to be increased in size. Another object of one embodiment of the present invention is to provide a semiconductor device or display system which consumes low power. Another object of one embodiment of the present invention is to provide a semiconductor device or display system capable of high-speed operation. Another object of one embodiment of the present invention is to provide a semiconductor device or display system with a small area.

Note that one embodiment of the present invention does not necessarily achieve all the objects listed above and only needs to achieve at least one of the objects. The description of the above objects does not preclude the existence of other objects. Other objects will be apparent from and can be derived from the description of the specification, the claims, the drawings, and the like.

A semiconductor device of one embodiment of the present invention includes a database, a first processing portion, and a second processing portion. The database has a function of storing first data and second data. The first data corresponds to an image displayed on a display portion comprising a pixel portion divided into N×M (N and M are each an integer of 2 or greater) regions, and the second data corresponds to an image intended to be displayed on the display portion. The first processing portion has a function of dividing the first data into N×M pieces of third data and dividing the second data into N×M pieces of fourth data. The second processing portion includes a neural network having a function of performing learning. The neural network having a function of performing learning has a function of performing learning with the use of the third data and the fourth data, and N×M weight coefficients obtained through the learning are output to a signal generation portion.

In the semiconductor device of one embodiment of the present invention, the neural network having a function of performing learning may have a function of performing learning with the use of the third data as learning data and the fourth data as teacher data.

Furthermore, in the semiconductor device of one embodiment of the present invention, the first data may be obtained through capturing an image displayed on the display portion.

A display system of one embodiment of the present invention includes an arithmetic portion including the above semiconductor device and the signal generation portion. The signal generation portion includes a reception portion, a third processing portion, a fourth processing portion, and a fifth processing portion. The reception portion has a function of receiving image data. The third processing portion has a function of dividing the image data into N×M pieces of fifth data. The fourth processing portion has a function of correcting the N×M pieces of fifth data. The fifth processing portion has a function of generating an image signal by uniting the N×M pieces of fifth data which are corrected. The fourth processing portion includes a neural network having a function of performing inference. The neural network having a function of performing inference has a function of correcting the fifth data through inference. The N×M weight coefficients are stored in the neural network having a function of performing inference.

In the display system of one embodiment of the present invention, the neural network having a function of performing inference may include a product-sum operation element. The product-sum operation element may include a memory circuit including a first transistor, a second transistor, and a capacitor. One of a source and a drain of the first transistor may be electrically connected to a gate of the second transistor and the capacitor. The first transistor may include a metal oxide in a channel formation region.

Furthermore, in the display system of one embodiment of the present invention, the pixel portion may include a plurality of pixels, and each of the plurality of pixels may include a light-emitting element.

According to one embodiment of the present invention, a novel semiconductor device or display system, a semiconductor device or display system enabling display of high-quality images, a semiconductor device or display system enabling a display portion to be increased in size, a semiconductor device or display system which consumes low power, a semiconductor device or display system capable of high-speed operation, or a semiconductor device or display system with a small area can be provided.

Note that the description of these effects does not preclude the existence of other effects. One embodiment of the present invention does not necessarily have all of these effects. Other effects will be apparent from and can be derived from the description of the specification, the claims, the drawings, and the like.

### BRIEF DESCRIPTION OF DRAWINGS

In the accompanying drawings:

FIG. 1 illustrates a structure example of a display system;

FIGS. 2A to 2C illustrate configuration examples of a display portion;

FIGS. 3A and 3B illustrate structural examples of a pixel portion;

FIGS. 4A to 4C illustrate configuration examples of a neural network;

FIG. 5 is a flow chart;

FIG. 6 is a flow chart;

FIG. 7 illustrates a configuration example of a semiconductor device;

FIG. 8 illustrates a configuration example of a memory circuit;

FIG. 9 illustrates a configuration example of a memory cell;

FIG. 10 illustrates a configuration example of a circuit;

FIG. 11 is a timing chart;

FIG. 12 illustrates a configuration example of a display portion;

FIG. 13 illustrates a structure example of a display device;

FIG. 14 illustrates a structure example of a display device;

FIGS. 15A to 15C illustrate a structure example of a transistor;

FIG. 16 is an energy band diagram;

FIG. 17 illustrates a structure example of a semiconductor device; and

FIGS. 18A to 18D illustrate structure examples of electronic devices.

### BEST MODE FOR CARRYING OUT THE INVENTION

Embodiments of the present invention will be described below in detail with reference to the drawings. However, the present invention is not limited to the following description and it is easily understood by those skilled in the art that the modes and details can be changed in various ways without departing from the spirit and scope of the present invention. Therefore, the present invention should not be interpreted as being limited to the description of the embodiments below.

One embodiment of the present invention includes, in its category, devices such as a semiconductor device, a memory device, a display device, an imaging device, and a radio frequency (RF) tag. The display device includes, in its category, a liquid crystal display device, a light-emitting device including pixels each provided with a light-emitting element typified by an organic light-emitting element, electronic paper, a digital micromirror device (DMD), a plasma display panel (PDP), a field emission display (FED), and the like.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. A metal oxide used in a channel region of a transistor, for example, is called an oxide semiconductor in some cases. That is to say, a metal oxide that has at least one of an amplifying function, a rectifying function, and a switching function can be called a metal oxide semiconductor, or OS for short. In the following description, a transistor including a metal oxide in a channel region is also referred to as an OS transistor.

In this specification and the like, a metal oxide including nitrogen is also called a metal oxide in some cases. Moreover, a metal oxide including nitrogen may be called a metal oxynitride. The details of a metal oxide will be described later.

In this specification and the like, an explicit description “X and Y are connected” means that X and Y are electrically connected, X and Y are functionally connected, and X and Y are directly connected. Accordingly, without limitation to a predetermined connection relation, for example, a connection relation shown in drawings or text, another connection relation is included in the drawings or the text. Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, and the case where X and Y are connected without the element that allows the electrical connection between X and Y provided therebetween.

In the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y, for example. Note that the switch is controlled to be turned on or off. That is, the switch is turned on or off to determine whether current flows therethrough or not. Alternatively, the switch has a function of selecting and changing a current path. Note that the case where X and Y are electrically connected includes the case where X and Y are directly connected.

In the case where X and Y are functionally connected, one or more circuits that enable functional connection between X and Y (e.g., a logic circuit such as an inverter, a NAND circuit, or a NOR circuit; a signal converter circuit such as a DA converter circuit, an AD converter circuit, or a gamma correction circuit; a potential level converter circuit such as a power source circuit (e.g., a step-up converter or a step-down converter) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; and/or a control circuit) can be connected between X and Y, for example. Even when another circuit is interposed between X and Y, for example, X and Y are functionally connected if a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

Note that components denoted by the same reference numerals in different drawings represent the same components, unless otherwise specified.

Even when independent components are electrically connected to each other in the drawing, one component has functions of a plurality of components in some cases. For example, when part of a wiring also serves as an electrode, one conductive film serves as the wiring and the electrode. Thus, “electrical connection” in this specification includes in its category such a case where one conductive film has functions of a plurality of components.

### Embodiment 1

In this embodiment, a semiconductor device and a display system of one embodiment of the present invention will be described.

### Structure Example of Display System

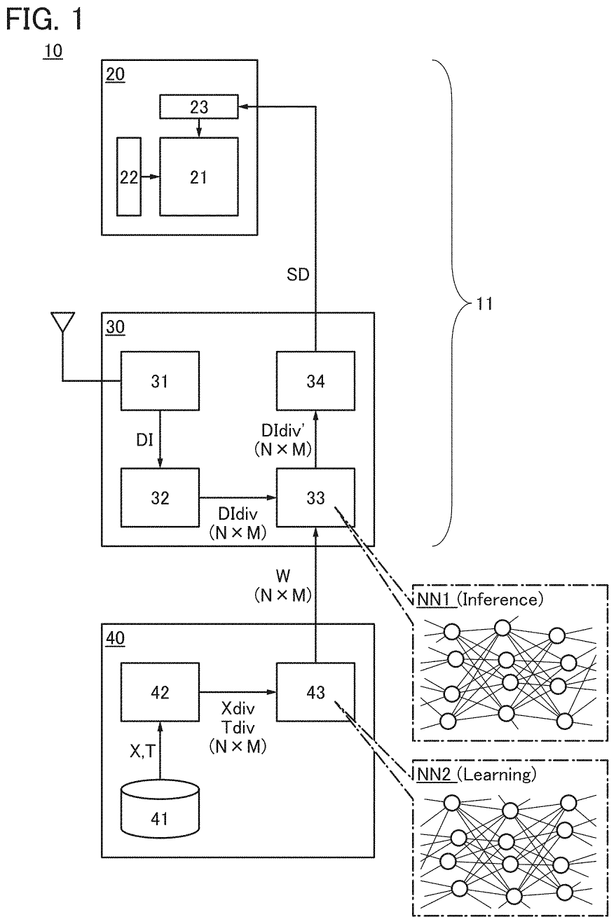

FIG. 1 illustrates a structure example of a display system 10. The display system 10 has a function of generating a signal for displaying an image on the basis of data received from the outside and displaying an image on the basis of the signal. The display system 10 includes a display portion 20, a signal generation portion 30, and an arithmetic portion 40. The display portion 20 and the signal generation portion 30 can be included in a display device 11. The arithmetic portion 40 can be an arithmetic device.

Note that a semiconductor device can constitute each of the display portion 20, the signal generation portion 30, and the arithmetic portion 40. Thus, the display portion 20, the signal generation portion 30, and the arithmetic portion 40 may be referred to as semiconductor devices.

### Display Portion

The display portion 20 has a function of displaying an image on the basis of a signal input from the signal generation portion 30. The display portion 20 includes a pixel portion 21, a driver circuit 22, and a driver circuit 23.

The pixel portion 21 includes a plurality of pixels and has a function of displaying an image. Each of the pixels includes a display element and has a function of displaying a predetermined gray level. The gray levels of the pixels are controlled by signals output from the driver circuits 22 and 23, whereby a predetermined image is displayed on the pixel portion 21.

The number of pixels included in the pixel portion 21 can be set freely. In order to display a high-resolution image, it is preferable to provide many pixels. For example, the number of provided pixels is preferably more than or equal to 1920×1080 in the case where a 2K image is displayed. Furthermore, the number of provided pixels is preferably more than or equal to 3840×2160 or more than or equal to 4096×2160 in the case where a 4K image is displayed. Moreover, the number of provided pixels is preferably more than or equal to 7680×4320 in the case where an 8K image is displayed. It is also possible to display an image with higher resolution than 8K on the display portion 21.

The driver circuit 22 has a function of supplying a signal for selecting the pixels (hereinafter, this signal is also referred to as a selection signal) to the pixel portion 21. The driver circuit 23 has a function of supplying a signal for displaying a predetermined image (hereinafter, this signal is also referred to as an image signal) to the pixel portion 21. An image signal is supplied to a pixel to which a selection signal has been supplied, and the pixel displays a predetermined gray level.

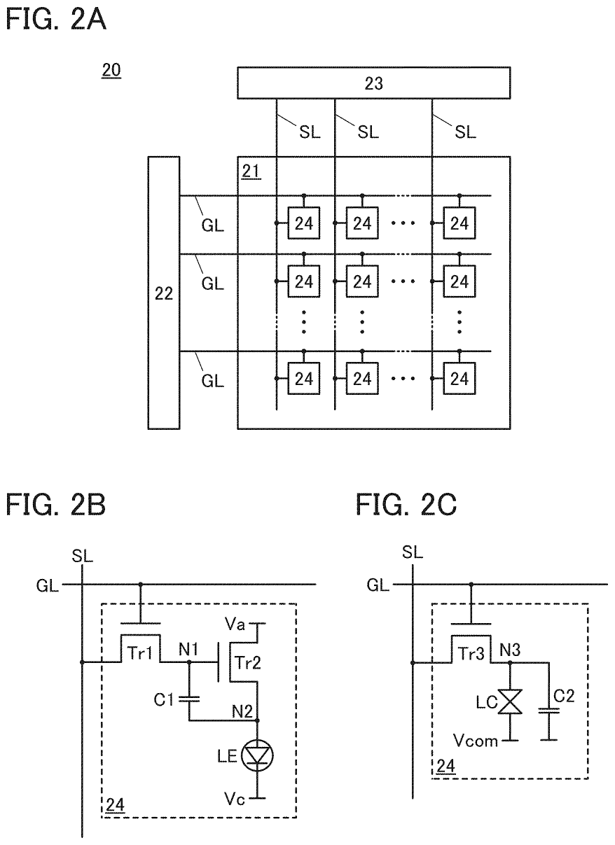

FIG. 2A illustrates a configuration example of the display portion 20. The pixel portion 21 includes a plurality of pixels 24, and the pixels 24 each include a display element. Examples of the display element in the pixel 24 include a liquid crystal element and a light-emitting element. As the liquid crystal element, a transmissive liquid crystal element, a reflective liquid crystal element, a transflective liquid crystal element, or the like can be used. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used as the display element, for example. Examples of the light-emitting element include self-luminous elements such as an organic light-emitting diode (OLED), a light-emitting diode (LED), a quantum-dot light-emitting diode (QLED), and a semiconductor laser.

The pixels 24 are connected to wirings SL and wirings GL. The wirings GL and the wirings SL are respectively connected to the driver circuit 22 and the driver circuit 23. The selection signals are supplied to the wirings GL, and image signals are supplied to the wirings SL.

The driver circuit 22 has a function of supplying the selection signals to the pixels 24. Specifically, the driver circuit 22 has a function of supplying the selection signals to the wirings GL, and the wirings GL each have a function of transmitting the selection signal output from the driver circuit 22 to the pixel 24. The wirings GL may also be referred to as selection signal lines or gate lines.

The driver circuit 23 has a function of supplying the image signals to the pixels 24. Specifically, the driver circuit 23 has a function of supplying the image signals to the wirings SL, and the wirings SL each have a function of transmitting the image signal output from the driver circuit 23 to the pixel 24. The wirings SL may also be referred to as image signal lines or source lines.

FIG. 2B illustrates a configuration example of the pixel 24 including a light-emitting element as a display element. The pixel 24 in FIG. 2B includes a transistor Tr1, a transistor Tr2, a capacitor C1, and a light-emitting element LE. Although the transistors Tr1 and Tr2 are n-channel transistors here, the polarity of the transistors can be changed as appropriate.

A gate of the transistor Tr1 is connected to the wiring GL. One of a source and a drain of the transistor Tr1 is connected to a gate of the transistor Tr2 and one electrode of the capacitor C1. The other of the source and the drain of the transistor Tr1 is connected to the wiring SL. One of a source and a drain of the transistor Tr2 is connected to the other electrode of the capacitor C1 and one electrode of the light-emitting element LE. The other of the source and the drain of the transistor Tr2 is connected to a wiring to which a potential Va is supplied. The other electrode of the light-emitting element LE is connected to a wiring to which a potential Vc is supplied. A node connected to the one of the source and the drain of the transistor Tr1, the gate of the transistor Tr2, and the one electrode of the capacitor C1 is referred to as a node N1. A node connected to the one of the source and the drain of the transistor Tr2 and the other electrode of the capacitor C1 is referred to as a node N2.

Here, the case where the potential Va is a high power supply potential and the potential Vc is a low power supply potential is described. The potential Va and the potential Vc can each be a common potential to the plurality of pixels 24. The capacitor C1 serves as a storage capacitor for holding a potential of the node N1.

Note that a source of a transistor in this specification and the like means a source region that is part of a semiconductor layer serving as a channel region, a source electrode connected to the semiconductor layer, or the like. Similarly, a drain of a transistor means a drain region that is part of the semiconductor layer, a drain electrode connected to the semiconductor layer, or the like. A gate of a transistor means a gate electrode or the like.

The terms “source” and “drain” of a transistor interchange with each other depending on the conductivity type of the transistor or levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, although the connection relationship of a transistor is described assuming that the source and the drain are fixed in some cases for convenience, actually, the names of the source and the drain interchange with each other depending on the relationship of the potentials.

The transistor Tr1 has a function of controlling the supply of a potential of the wiring SL to the node N1. Specifically, a potential of the wiring GL is controlled to turn on the transistors Tr1, whereby the potential of the wiring SL corresponding to an image signal is supplied to the node N1, and thus is written to the pixel 24. After that, the potential of the wiring GL is controlled to turn off the transistor Tr1, whereby the potential of the node N1 is held.

Then, the amount of current flowing between the source and the drain of the transistor Tr2 is controlled in accordance with the voltage between the nodes N1 and N2. The light-emitting element LE emits light with a luminance corresponding to the amount of flowing current. Accordingly, the gray level of the pixel 24 can be controlled. Note that the transistor Tr2 preferably operates in a saturation region.

FIG. 2C illustrates a configuration example of a pixel 24 including a liquid crystal element as the display element. The pixel 24 in FIG. 2C includes a transistor Tr3, a capacitor C2, and a liquid crystal element LC. Although the transistor Tr3 is an n-channel transistor here, the polarity of the transistor can be changed as appropriate.

A gate of the transistor Tr3 is connected to the wiring GL. One of a source and a drain of the transistor Tr3 is connected to one electrode of the liquid crystal element LC and one electrode of the capacitor C2. The other of the source and the drain of the transistor Tr3 is connected to the wiring SL. The other electrode of the liquid crystal element LC is connected to a wiring to which a potential Vcom is supplied. The other electrode of the capacitor C2 is connected to a wiring to which a predetermined potential is supplied. A node connected to the one of the source and the drain of the transistor Tr3, the one electrode of the liquid crystal element LC, and the one electrode of the capacitor C2 is referred to as a node N3.

The potential Vcom can be a common potential to the plurality of pixels 24. The potential Vcom may be the same as a potential of a wiring connected to the other electrode of the capacitor C2. The capacitor C2 serves as a storage capacitor for holding the potential of the node N3.

The transistor Tr3 has a function of controlling the supply of the potential of the wiring SL to the node N3. Specifically, the potential of the wiring GL is controlled to turn on the transistor Tr3, whereby the potential of the wiring SL corresponding to an image signal is supplied to the node N3, and thus is written to the pixel 24. After that, the potential of the wiring GL is controlled to turn off the transistor Tr3, whereby the potential of the node N3 is held.

The liquid crystal element LC includes a pair of electrodes and a liquid crystal layer containing a liquid crystal material to which the voltage between the pair of electrodes is applied. The alignment of liquid crystal molecules included in the liquid crystal element LC changes in accordance with the value of the voltage applied between the pair of electrodes, and thus the transmittance of the liquid crystal layer is changed. Therefore, when the potential supplied from the wiring SL to the node N3 is controlled, the gray level of the pixel 24 can be controlled.

The above operation is performed for the wirings GL one by one, whereby an image for a first frame can be displayed.

The selection of the wirings GL may be performed by either progressive scan or interlaced scan. The supply of image signals to the wirings SL may be performed by dot sequential driving in which the image signals are sequentially supplied to the wirings SL, or line sequential driving in which the image signals are concurrently supplied to all the wirings SL. Alternatively, supply of image signals may be performed for every set of wirings SL.

Next, in a second frame period, an image is displayed by an operation similar to that of a first frame period. Thus, the image displayed on the pixel portion 21 is rewritten.

As the semiconductor of the transistors included in the pixels 24, a Group 14 element such as silicon or germanium, a compound semiconductor such as gallium arsenide, an organic semiconductor, a metal oxide, or the like can be used. Alternatively, the semiconductor may be a non-single-crystal semiconductor (e.g., amorphous semiconductor, microcrystalline semiconductor, or polycrystalline semiconductor) or a single crystal semiconductor.

The transistors included in the pixels 24 preferably include an amorphous semiconductor, in particular, hydrogenated amorphous silicon (a-Si:H) in channel formation regions. Because the transistors including an amorphous semiconductor can be easily formed over a large-sized substrate, the manufacturing process of a large-screen display device which is compatible with 2K, 4K, or 8K broadcasting or the like can be simplified, for example.

Furthermore, the transistors in the pixel 24 may be transistors including metal oxides in their channel formation regions (such transistors are referred to as OS transistors). An OS transistor has higher field-effect mobility than a transistor including hydrogenated amorphous silicon. In addition, an OS transistor does not require a crystallization process which has been necessary for a transistor using polycrystalline silicon or the like.

Because an OS transistor has an extremely low off-state current, in the case where an OS transistor is used as the transistor Tr1 or Tr3, an image signal can be held in the pixel 24 for a significantly long period. This enables the update frequency of an image signal to be extremely low in a period when there is no change in the image displayed on the pixel portion 21 or a period when the change is at a certain level or lower. The update frequency of the image signal can be, for example, less than once every 0.1 seconds, less than once every second, or less than once every 10 seconds. In particular, when many pixels 24 are provided for 2K, 4K, or 8K broadcasting or the like, the low-frequency update of the image signal can effectively reduce the power consumption.

The gray levels of the pixels 24 are controlled by controlling current flowing in the light-emitting elements LE or voltage applied to the liquid crystal elements LC. Here, the gray levels of the pixels 24 can vary because of a variation in potentials supplied to the pixels 24, a variation in transistor characteristics or capacitance values of capacitors in the pixels 24, or the like. For example, when a common potential (e.g., the potential Va, Vc, or Vcom) is supplied to the plurality of pixels 24, influence of voltage drop varies in accordance with the distance between a supply source of the potential and each of the pixels 24, so that the values of potentials supplied to the pixels 24 may vary. In the case where a large-sized display portion 20 that is compatible with 2K, 4K, or 8K broadcasting is manufactured, in particular, the area of the pixel portion 21 is increased, and thus the influence of voltage drop due to the wiring resistance is more noticeable.

Furthermore, in the case where light-emitting elements are used as the display elements, there may be a variation in current supplied to the light-emitting elements due to the influence of voltage drop, which is mentioned above, or the like. Then, the variation in current causes a variation in luminance of the light-emitting elements. In particular, a variation in luminance at the time when the light-emitting elements emit light at low luminance is increased. Thus, a phenomenon in which the light-emitting elements slightly emit light at the time of black display, a phenomenon in which dark black and light black coexist at the time of black display, or the like may occur, degrading the display quality. In this way, influence of a variation in gray levels is particularly noticeable when light-emitting elements are used.

Thus, in one embodiment of the present invention, the pixel portion 21 is divided into a plurality of regions, and the gray level is corrected in each of the regions by utilizing artificial intelligence (AI). Specifically, learning of an artificial neural network (ANN) is performed using data corresponding to the image that is actually displayed on the display portion 20 and data corresponding to an ideal image that is intended to be displayed on the display portion 20, as learning data and teacher data, respectively. Then, on the basis of the result of the learning, the gray levels of the pixels 24 are corrected from divided region to region, whereby a variation in the gray levels is compensated. Accordingly, display of a high-quality image becomes possible. Hereinafter, the structure of the display portion 20 in which the pixel portion 21 is divided will be described in detail.

Note that artificial intelligence refers to computers that imitate the intelligence of human beings. An artificial neural network is a circuit that imitates a neural network made up of neurons and synapses, and is capable of determining the connection strength (weight coefficient) between neurons through learning. In addition, forming a neural network with the use of the weight coefficients obtained through learning and drawing a new conclusion from that is called inference (recognition). Note that an artificial neural network is a type of artificial intelligence. In this specification and the like, a term “neural network” particularly refers to artificial neural network.

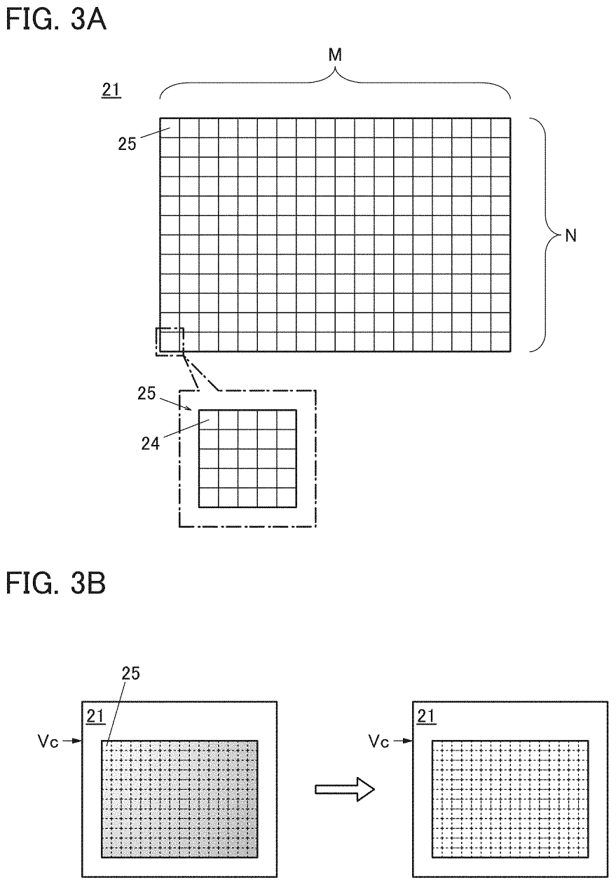

In FIG. 3A, a structure example of the pixel portion 21 which is divided into a plurality of regions is shown. The pixel portion 21 is divided into regions 25 in N rows and M columns (N and M are each an integer of 2 or greater), and each of the regions 25 includes a plurality of pixels 24. Then, the correction of gray level is performed in each of the regions 25.

As an example, a case where the potential Vc is supplied to the pixel portion 21 as illustrated in FIG. 3B is described. Although the potential Vc supplied to the pixel portion 21 is supplied to each of the regions 25, the potential Vc supplied to the regions 25 may have variations because the influence of voltage drop is increased as the distance from the input portion of the potential Vc to the region 25 increases. Thus, variations in gray level of the pixels 24 are radially distributed in accordance with the distance from the input portion of the potential Vc. In one embodiment of the present invention, the correction of gray levels of the pixels 24 can be made in each of the regions 25 in accordance with the distance from the input portion of the potential Vc. Thus, it is possible to control the degree of correction in such a manner that the degree of correction is increased in the region 25 that is farther from the input portion of the potential Vc, for example, whereby the correction of gray levels can accurately be made.

The gray levels can be corrected by correction of image data with the use of artificial intelligence in the signal generation portion 30. Hereinafter, a structure example of the signal generation portion 30 will be described in detail.

### Signal Generation Portion

The signal generation portion 30 shown in FIG. 1 has a function of generating an image signal on the basis of a signal input from the outside. The signal generation portion 30 includes a reception portion 31, a processing portion 32, a processing portion 33, and a processing portion 34.

The reception portion 31 has a function of receiving a signal transmitted from the outside and performing signal processing. Data corresponding to an image to be displayed on the display portion 20 (hereinafter such data is also referred to as image data), such as a broadcast signal, is input to the reception portion 31. The reception portion 31 can have a function of demodulation, analog-digital conversion, or the like of a received signal. The reception portion 31 may also have a function of correcting an error. A signal subjected to a variety of processing in the reception portion 31 is output to the processing portion 32 as image data DI.

Examples of the broadcast signal that the reception portion 31 can receive include a ground wave and a wave transmitted from a satellite. The reception portion 31 can receive a broadcast including video and sound, a broadcast only including sound, and the like. The broadcast received by the reception portion 31 may be an analog broadcast or a digital broadcast.

Furthermore, the reception portion 31 can receive airwaves transmitted in a certain frequency band, such as a UHF band (about 300 MHz to 3 GHz) or a VHF band (30 MHz to 300 MHz), for example. When a plurality of broadcast signals received in a plurality of frequency bands is used, the transfer rate can be increased and more information can thus be obtained. In this manner, an image (e.g., a 2K, 4K, or 8K image) with higher resolution than that of full high definition can be easily displayed on the display portion 20.

The processing portion 32 has a function of dividing the image data input from the reception portion 31. Specifically, the data DI is divided into N×M pieces of data DIdiv. Note that the number of divisions of the data DI is equal to the number of regions 25 in FIG. 3A, and each piece of data DIdiv corresponds to image data for displaying an image on the region 25. The N×M pieces of data DIdiv generated by the processing portion 32 are output to the processing portion 33.

Note that the processing portion 32 may have a function of performing image processing on the data DI, in addition to a function of dividing the data DI. Examples of the image processing performed by the processing portion 32 include noise removal, gray level conversion, tone correction, and luminance correction. The tone correction and luminance correction can be performed with the use of gamma correction, for example. Furthermore, the processing portion 32 may have a function of pixel interpolation in accordance with up-conversion of the resolution, a function of frame interpolation in accordance with up-conversion of the frame frequency, or the like.

The noise removal processing include removal of a variety of noise, such as mosquito noise which appears near the contour of texts and the like, block noise which appears in high-speed moving images, random noise causing flicker, and dot noise caused by up-conversion of the resolution.

The gray level conversion process converts the gray level of an image to a gray level corresponding to output characteristics of the display portion 20. For example, in the case where the number of gray levels is increased, gradation values of pixels are interpolated and assigned to respective images inputted with low gray levels, so that a smooth histogram can be obtained. In addition, high-dynamic range (HDR) processing for increasing the dynamic range is also included in the gray level conversion processing.

The pixel interpolation process interpolates data which does not actually exist when resolution is up-converted. For example, referring to pixels around the target pixel, data is interpolated to display intermediate color between the pixels.

The tone correction process corrects the tone of an image. The luminance correction process corrects the brightness (luminance contrast) of an image. The luminance and tone of an image displayed on the display portion 20 are corrected to be optimal, in accordance with the kind, luminance, or color purity of lighting of a room in which the display portion 20 is provided, for example.

In the case where the frame frequency of a displayed image is increased, the frame interpolation generates an image for a frame that does not exist originally (interpolation frame). For example, an image for an interpolation frame which is interposed between two images is generated from a difference between the two images. Alternatively, images for a plurality of interpolation frames can be generated between two images. For example, when the frame frequency of image data is 60 Hz, a plurality of interpolation frames are generated, and the frame frequency of an image signal outputted to the display portion 20 can be increased twofold (120 Hz), fourfold (240 Hz), eightfold (480 Hz), or the like.

Note that it is also possible to perform the above image processing by an image processing circuit that is provided separately from the processing portion 32.

The processing portion 33 has a function of correcting the data DIdiv so as to compensate a variation in gray level of an image displayed on the display portion 20. Specifically, the processing portion 33 includes a neural network NN1, and the data DIdiv is corrected to be data DIdiv′ by inference of the neural network NN1. Output data from the neural network NN1 is output as the data DIdiv′ to the processing portion 34.

The neural network NN1 has a function of performing inference using the data DIdiv as input data and generating image data for displaying an image in which a variation in gray level is reduced to a certain level or less. Specifically, in the neural network NN1, learning is performed such that the data DIdiv is corrected to display an intended image on the display portion 20 by inference, and weight coefficients are set.

The processing portion 33 preferably has a function of making correction of the N×M pieces of data DIdiv by parallel processing. Thus, the data DIdiv′ can be generated at high speed. For example, a plurality of neural networks NN1 may be provided in the processing portion 33 so as to perform inference in parallel, or the number of neurons in an input layer of the neural network NN1 may be increased.

The processing portion 34 has a function of uniting a plurality of pieces of data. Specifically, the processing portion 34 has a function of uniting the N×M pieces of data DIdiv′ to generate image signals (signals SD) which are supplied to the display portion 20. The signals SD generated by the processing portion 34 are output to the display portion 20.

Note that learning of the neural network NN1 can be performed outside of the signal generation portion 30. In that case, weight coefficients obtained through learning performed outside are stored in the neural network NN1, whereby the result of the learning can be reflected in the neural network NN1. Hereinafter, a structure example of the arithmetic portion 40 capable of performing learning of the neural network NN1 will be described in detail.

### Arithmetic Portion

The arithmetic portion 40 has a function of performing learning of a neural network. As the arithmetic portion 40, an arithmetic device with high arithmetic processing capability such as a dedicated server or a cloud can be used. The arithmetic portion 40 includes a database 41, a processing portion 42, and a processing portion 43. Note that the database 41 may be provided outside of the arithmetic portion 40.

The database 41 has a function of storing data used for learning of the neural network. Specifically, the database 41 has a function of storing learning data and teacher data input to the neural network.

In one embodiment of the present invention, data X and data T are stored in the database 41. The data X corresponds to the image that is actually displayed on the display portion 20. The data T corresponds to an ideal image that is intended to be displayed on the display portion 20. The data X and the data T are collected in advance as samples for learning, and stored in the database 41. The data X and the data T read out from the database 41 are output to the processing portion 42.

Note that the data X can be obtained by conducting a display test or the like and capturing, by an image sensor or the like, an image actually displayed on the display portion 20, for example.

The processing portion 42 has a function of dividing the data input from the database 41. Specifically, the data X is divided into N×M pieces of data Xdiv and the data T is divided into N×M pieces of data Tdiv. The number of divisions of each of the data X and the data T is the same as the number of regions 25 in FIG. 3A, and each piece of data Xdiv and each piece of data Tdiv correspond to image data of an image displayed on the region 25.

Note that the processing portion 42 may have a function of generating a histogram from the data X which is divided and outputting the histogram as the data Xdiv. In addition, the processing portion 42 may have a function of generating a histogram from the data T which is divided and outputting the histogram as the data Tdiv.

The processing portion 43 has a function of performing learning of a neural network so as to enable generation of image data for displaying an image in which the variation in gray level is reduced to a certain level or less. Specifically, the processing portion 43 includes a neural network NN2 that corresponds to the structure of the neural network NN1 provided in the signal generation portion 30. In order that the structure of the neural network NN2 may correspond to the structure of the neural network NN1, the neural network NN1 and the neural network NN2 are formed as hierarchical perceptron neural networks having the same number of layers and the same number of neurons included in each layer, for example.

The neural network NN2 has a function of performing supervised learning. Specifically, the neural network NN2 performs learning using the data Xdiv as learning data and the data Tdiv as teacher data. When the data Xdiv and the data Tdiv are input to the neural network NN2, weight coefficients of the neural network NN2 are set so that an error between output data of the neural network NN2 and the data Tdiv is a certain level or less. Thus, learning of the neural network NN2 is performed so that an image with a variation in gray level is converted into an ideal image. Note that a backpropagation method or the like can be used to set the weight coefficients.

The initial values of the weight coefficients of the neural network NN2 may be random numbers. The initial values of the weight coefficients might affect the speed of learning (e.g., the convergent rate of weight coefficients and the prediction accuracy of the neural network). Thus the initial values of the weight coefficients may be changed when the learning speed is low. When the error between the output data of the neural network NN2 and the data Tdiv finally becomes the certain level or less, the learning of the neural network NN2 is completed. A set of the weight coefficients of the neural network NN2 at the completion of learning is collectively referred to as a weight coefficient W.

Note that the learning of the neural network NN2 is performed for each of the regions 25 shown in FIG. 3A, using one piece of data Xdiv and one piece of data Tdiv. Accordingly, through learning with the use of the N×M pieces of data Xdiv and the N×M pieces of data Tdiv, N×M weight coefficients W are obtained.

When the learning of the neural network NN2 is completed, the N×M weight coefficients W are input to the processing portion 33, and the weight coefficients W are stored in the neural network NN1. Accordingly, the result of learning of the neural network NN2 can be reflected in the neural network NN1. Then, the neural network NN1 can correct the data DIdiv to the data DIdiv′ with the use of the result of the learning.

A case where a neural network NN2 that increases the gray level of a predetermined region 25 to obtain an ideal image is formed by learning is described, as an example. When the weight coefficient W at this time is stored in the neural network NN1 and the data DIdiv is input to the processing portion 33, the data DIdiv is corrected to increase the gray level of the predetermined region 25. In this manner, by reflecting the difference in gray level on the data DIdiv in advance, an intended image can be displayed on the display portion 20.

As described above, learning of the neural network is performed in the arithmetic portion 40, and the result of the learning is reflected in the neural network NN1 included in the signal generation portion 30; accordingly, hardware for forming a neural network having a learning function need not be provided in the signal generation portion 30. Thus, the structure of the signal generation portion 30 can be simplified and its area can be smaller.

Note that the neural network NN2 may be composed of hardware or may be formed on software. In the case where the neural network NN2 is formed on software, a memory device in which the software is stored or the like is provided in the processing portion 43.

As described above, the gray levels of the pixels 24 are controlled in each region 25 by utilizing artificial intelligence, so that display of a high-quality image becomes possible. In addition, the variation in gray level due to voltage drop can effectively be compensated, which enables increase in size of the display portion 20.

Note that, in the above description, the number of rows and columns of regions 25 are each 2 or greater (i.e., N and M are each 2 or greater), however, the correction of gray levels may be performed for each row of regions 25 (i.e., M=1) or for each column of regions 25 (i.e., N=1).

### Configuration Example of Neural Network

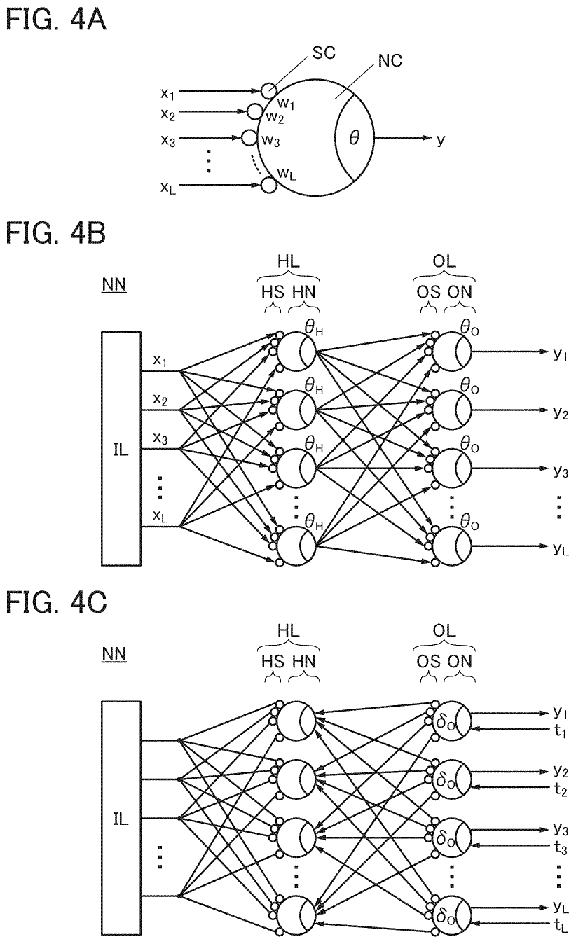

Next, configuration examples of a neural network having a learning function will be described. FIGS. 4A to 4C illustrate configuration examples of a neural network NN. The neural network NN includes neuron circuits and synapse circuits provided between the neuron circuits.

FIG. 4A illustrates configuration examples of a neuron circuit NC and synapse circuits SC that constitute the neural network NN. Input data x₁ to x_{L} (L is a natural number) are input to the synapse circuits SC. In addition, the synapse circuits SC each have a function of storing a weight coefficient wₖ (k is an integer of 1 to L inclusive). The weight coefficient wₖ corresponds to the connection strength between the neuron circuits NC.

When the input data x₁ to x_{L} are input to the synapse circuits SC, the sum of the products (xₖwₖ) for k=1 to L (i.e., x₁w₁+x₂w₂+ . . . +x_{L}w_{L}) of input data xₖ input to the synapse circuit SC and the weight coefficient wₖ stored in the synapse circuit SC, that is, a value obtained by the product-sum operation of xₖ and wₖ is supplied to the neuron circuit NC. When the value is larger than the threshold θ of the neuron circuit NC, the neuron circuit NC outputs a high-level signal y. This phenomenon is referred to as firing of the neuron circuit NC.

FIG. 4B shows a model of a hierarchical perceptron neural network NN using the neuron circuits NC and the synapse circuits SC. The neural network NN includes an input layer IL, a hidden layer (middle layer) HL, and an output layer OL.

The input data x₁ to x_{L} are output from the input layer IL. The hidden layer HL includes hidden synapse circuits HS and hidden neuron circuits HN. The output layer OL includes output synapse circuits OS and output neuron circuits ON.

A value obtained by the product-sum operation using the input data xₖ and the weight coefficient wₖ that is held in the hidden synapse circuit HS is supplied to the hidden neuron circuit HN. Then, a value obtained by the product-sum operation using the output of the hidden neuron circuit HN and the weight coefficient wₖ that is held in the output synapse circuit OS is supplied to the output neuron circuit ON. Then, output data y₁ to y_{L} are output from the output neuron circuits ON.

As described above, the neural network NN to which given input data is supplied has a function of outputting, as output data, values corresponding to weight coefficients held in the synapse circuits SC and thresholds θ of the neuron circuits.

In addition, the neural network NN can perform supervised learning by the input of teacher data. FIG. 4C shows a model of the neural network NN which performs supervised learning using a backpropagation method.

The backpropagation method is a method for changing a weight coefficient wₖ of a synapse circuit so that the error between output data from a neural network and a teacher signal is reduced. Specifically, a weight coefficient wₖ of the hidden synapse circuit HS is changed in accordance with an error δ_{O} that is determined on the basis of the output data (data y₁ to y_{L}) and the teacher data (data t₁ to t_{L}). In addition, a weight coefficient wₖ of a synapse circuit SC in the previous stage is changed in accordance with the amount of change in the weight coefficient wₖ of the hidden synapse circuit HS. In this manner, weight coefficients of the synapse circuits SC are sequentially changed on the basis of the teacher data t₁ to t_{L}, so that the neural network NN can perform learning.

The configurations of neural networks shown in FIGS. 4A to 4C can be used for the neural networks NN1 and NN2 in FIG. 1. Furthermore, the above-mentioned backpropagation method can be used for the learning of the neural network NN2. In that case, the data Xdiv is used as the input data x₁ to x_{L}, and the data Tdiv is used as the teacher data t₁ to t_{L}.

Note that the number of hidden layers HL is one in each of FIGS. 4B and 4C, but can be two or greater. The use of a neural network including two or more hidden layers HL (such a neural network is referred to as a deep neural network (DNN)) enables deep learning. Thus, the accuracy of gray level correction can be improved.

### Operative Example of Display System

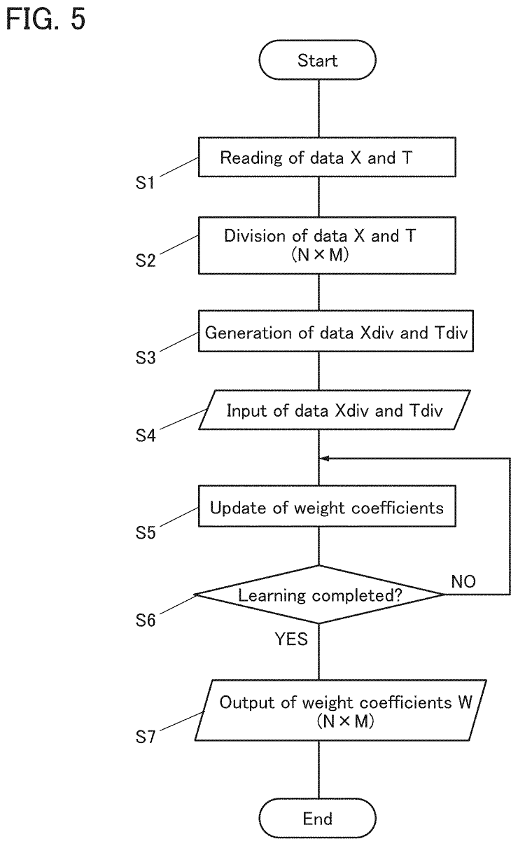

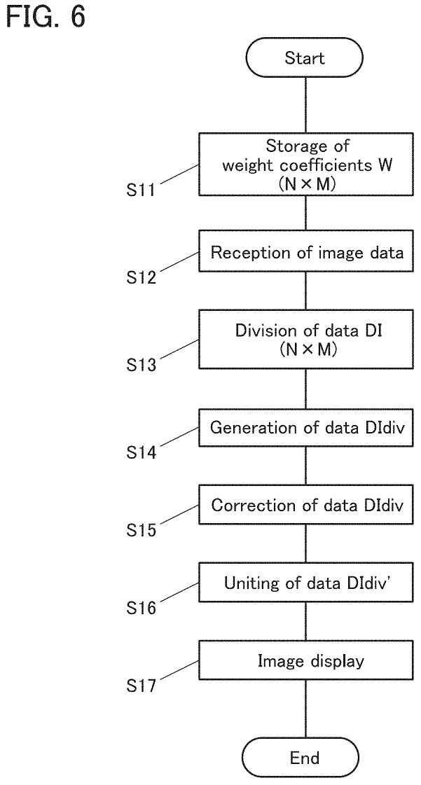

Next, an operation example of the above-described display system 10 will be described. FIG. 5 is a flow chart showing an operation example of learning of the neural network. FIG. 6 is a flow chart showing an operation example of gray level correction through inference of the neural network.

### Learning

Learning of the neural network is described with reference to FIG. 5. First, in the arithmetic portion 40, the data X and the data T are read from the database 41 (Step S1). As mentioned above, the data X corresponds to the image that is actually displayed on the display portion 20, and the data T corresponds to an ideal image that is intended to be displayed on the display portion 20. Then, the data X and the data T are each divided into N×M pieces of data in the processing portion 42 (Step S2). Accordingly, N×M pieces of data Xdiv and N×M pieces of data Tdiv are generated (Step S3).

Note that the processing portion 42 may generate histograms of the data X and the data T each of which is divided. In that case, the histogram of the data X which is divided is used as the data Xdiv, and the histogram of the data T which is divided is used as the data Tdiv.

Next, the data Xdiv and the data Tdiv are input to the processing portion 43 (Step S4). Then, learning of the neural network NN2 is performed using the data Xdiv and the data Tdiv.

Specifically, the neural network NN2 updates weight coefficients using the data Xdiv as learning data and the data Tdiv as teacher data (Step S5). Then, the update of weight coefficients is repeated until the error between the output data from the neural network NN2 and the data Tdiv becomes a certain level or less (NO in Step S6). When the error becomes a certain level or less, the learning is completed (YES in Step S6).

Then, N×M weight coefficients W obtained through learning are output to the processing portion 33 in the signal generation portion 30 (Step S7), and stored in the neural network NN1. Accordingly, the result of learning of the neural network NN2 can be reflected in the neural network NN1.

Through the above operation, learning of the neural network in the arithmetic portion 40 is performed.

### Inference

Next, inference of the neural network is described with reference to FIG. 6. First, N×M weight coefficients W obtained through the above learning are stored in the neural network NN1 (Step S11). Thus, a function of compensating the variation in gray level is added to the processing portion 33.

Next, image data is received by the reception portion 31 in the signal generation portion 30 (Step S12). Then, the image data subjected to appropriate processing by the reception portion 31 is output as data DI to the processing portion 32.

The data DI which is input to the processing portion 32 is then divided into N×M pieces of data (Step S13). Thus, N×M pieces of data DIdiv are generated (Step S14).

Next, the N×M pieces of data DIdiv are input to the processing portion 33 where an operation is carried out. Specifically, inference of the neural network NN1 is performed using the data DIdiv as input data, and data DIdiv′ is output from the output layer of the neural network NN1. Thus, the data DIdiv is corrected so as to compensate the variation in gray level of an image displayed on the pixel portion 21 (Step S15).

Note that when the correction of the N×M pieces of data DIdiv is made through parallel processing, the N×M pieces of data DIdiv′ can be generated quickly.

Next, the N×M pieces of data DIdiv′ are input to the processing portion 34. Then, the processing portion 34 generates image signals by uniting the N×M pieces of data DIdiv′ (Step S16). The generated image signals are then supplied as signals SD to the driver circuit 23, and an image in which the variation in gray level is compensated is displayed on the pixel portion 21 (Step S17).

Through the above operation, the image data received by the signal generation portion 30 is corrected, and display of an image in which the variation in gray level is reduced becomes possible.

As described above, in one embodiment of the present invention, learning of the neural network is performed using data corresponding to the image that is actually displayed on the display portion 20 and data corresponding to an ideal image that is intended to be displayed on the display portion 20 as learning data and teacher data, respectively. Then, through inference with the use of the neural network after the learning, image signals for displaying an image in which the variation in gray level is compensated are generated. In this manner, the quality of an image displayed on the display portion 20 can be improved.

In this embodiment, the configuration in which the neural network is provided in the processing portion 33 is described; however, a neural network may be incorporated in the processing portion 32 in the case where image processing is performed in the processing portion 32. In that case, image processing using the neural network, such as tone correction in accordance with people, buildings, scenery, or the like, a processing of sharpening the contours of objects displayed in an image, processing of up-converting image data with low resolution, gamma correction, data compression, or the like can be performed.

This embodiment can be combined with any of the other embodiments as appropriate.

### Embodiment 2

In this embodiment, configuration examples of semiconductor devices that can be used in the neural networks described in Embodiment 1 will be described.

In the case where a neural network is composed of hardware, product-sum operations in the neural network can be performed with the use of product-sum operation elements. In this embodiment, configuration examples of semiconductor devices that can be used as product-sum operation elements in the neural network NN1 or the neural network NN2 will be described.

### Configuration Example of Semiconductor Device

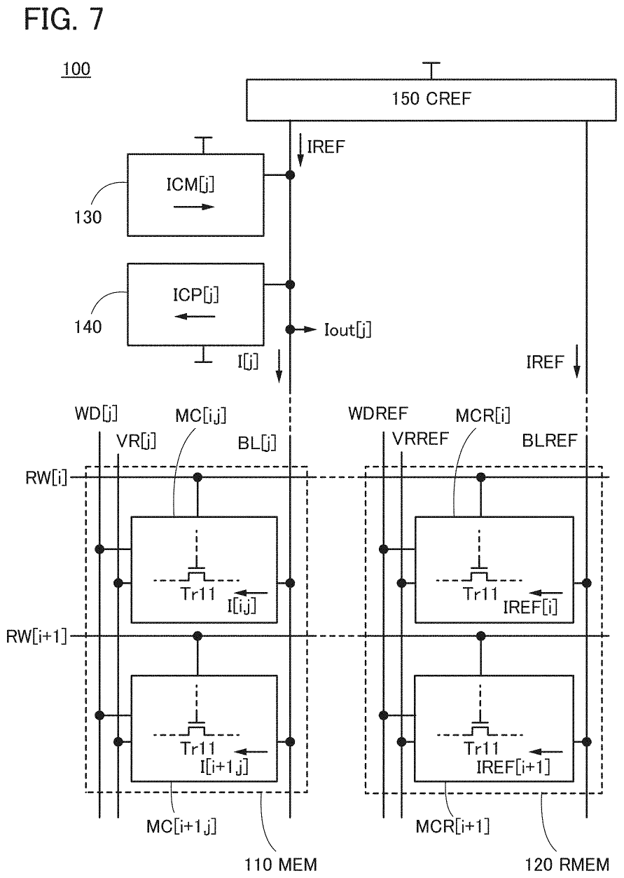

FIG. 7 illustrates a configuration example of a semiconductor device 100. The semiconductor device 100 illustrated in FIG. 7 includes a memory circuit 110 (MEM), a reference memory circuit 120 (RMEM), a circuit 130, and a circuit 140. The semiconductor device 100 may further include a current supply circuit 150 (CREF).

The memory circuit 110 (MEM) includes a memory cell MC such as a memory cell MC[i,j] and a memory cell MC[i+1,j]. The memory cell MC includes an element that has a function of converting an input potential into current. As the element having such a function, an active element such as a transistor can be used, for example. FIG. 7 illustrates an example where the memory cell MC includes a transistor Tr11.

A first analog potential is input to the memory cell MC through a wiring WD such as a wiring WD[j]. The first analog potential corresponds to first analog data. The memory cell MC has a function of generating a first analog current corresponding to the first analog potential. Specifically, drain current of the transistor Tr11, which is obtained when the first analog potential is supplied to a gate of the transistor Tr11, can be used as the first analog current. Hereinafter, current flowing in the memory cell MC[i,j] is denoted by I[i,j], and current flowing in the memory cell MC[i+1,j] is denoted by I[i+1,j].

Note that the drain current of the transistor Tr11 operating in a saturation region is not dependent on voltage between a source and a drain and is controlled by the difference between its gate voltage and threshold voltage. Thus, the transistor Tr11 desirably operates in a saturation region. The gate voltage and the voltage between the source and the drain of the transistor Tr11 are each appropriately set to a voltage at which the transistor Tr11 operates in a saturation region.

Specifically, in the semiconductor device 100 illustrated in FIG. 7, a first analog potential Vx[i,j] or a potential corresponding to the first analog potential Vx[i,j] is input to the memory cell MC[i,j] through the wiring WD[j]. The memory cell MC[i,j] has a function of generating a first analog current corresponding to the first analog potential Vx[i,j]. This means that the current I[i,j] flowing in the memory cell MC[i,j] corresponds to the first analog current, in this case.

Furthermore, in the semiconductor device 100 illustrated in FIG. 7, a first analog potential Vx[i+1,j] or a potential corresponding to the first analog potential Vx[i+1,j] is input to the memory cell MC[i+1,j] through the wiring WD[j]. The memory cell MC[i+1,j] has a function of generating a first analog current corresponding to the first analog potential Vx[i+1,j]. This means that the current I[i+1,j] flowing in the memory cell MC[i+1,j] corresponds to the first analog current, in this case.

The memory cell MC has a function of holding the first analog potential. In other words, the memory cell MC has a function of holding the first analog current corresponding to the first analog potential.

Moreover, a second analog potential is input to the memory cell MC through a wiring RW such as a wiring RW[i] and a wiring RW[i+1]. The second analog potential corresponds to second analog data. The memory cell MC has a function of adding the second analog potential or a potential corresponding to the second analog potential to the first analog potential that is held and a function of holding a third analog potential obtained by the addition. The memory cell MC also has a function of generating a second analog current corresponding to the third analog potential. In other words, the memory cell MC has a function of holding the second analog current corresponding to the third analog potential.

Specifically, in the semiconductor device 100 illustrated in FIG. 7, a second analog potential Vw[i,j] is input to the memory cell MC[i,j] through the wiring RW[i]. The memory cell MC[i,j] has a function of holding a third analog potential corresponding to the first analog potential Vx[i,j] and the second analog potential Vw[i,j]. The memory cell MC[i,j] also has a function of generating a second analog current corresponding to the third analog potential. This means that the current I[i,j] flowing in the memory cell MC[i,j] corresponds to the second analog current, in this case.

Furthermore, in the semiconductor device 100 illustrated in FIG. 7, a second analog potential Vw[i+1,j] is input to the memory cell MC[i+1,j] through the wiring RW[i+1]. The memory cell MC[i+1,j] has a function of holding the first analog potential Vx[i+1,j] and a third analog potential corresponding to the second analog potential Vw[i+1,j]. The memory cell MC[i+1,j] also has a function of generating a second analog current corresponding to the third analog potential. This means that the current I[i+1,j] flowing in the memory cell MC[i+1,j] corresponds to the second analog current, in this case.

The current I[i,j] flows between a wiring BL[j] and a wiring VR[j] through the memory cell MC[i,j]. The current I[i+1,j] flows between the wiring BL[j] and the wiring VR[j] through the memory cell MC[i+1,j]. Accordingly, a current I[j], which corresponds to the sum of the current I[i,j] and the current I[i+1,j], flows between the wiring BL[j] and the wiring VR[j] through the memory cell MC[i,j] and the memory cell MC[i+1,j].

The reference memory circuit 120 (RMEM) includes a memory cell MCR such as a memory cell MCR[i] and a memory cell MCR[i+1]. Note that a first reference potential VPR is input to the memory cell MCR through a wiring WDREF. The memory cell MCR has a function of generating a first reference current corresponding to the first reference potential VPR. Hereinafter, current flowing in the memory cell MCR[i] is denoted by IREF[i], and current flowing in the memory cell MCR[i+1] is denoted by IREF[i+1].

Specifically, in the semiconductor device 100 illustrated in FIG. 7, the first reference potential VPR is input to the memory cell MCR[i] through the wiring WDREF. The memory cell MCR[i] has a function of generating the first reference current corresponding to the first reference potential VPR. This means that the current IREF[i] flowing in the memory cell MCR[i] corresponds to the first reference current, in this case.

Furthermore, in the semiconductor device 100 illustrated in FIG. 7, the first reference potential VPR is input to the memory cell MCR[i+1] through the wiring WDREF. The memory cell MCR[i+1] has a function of generating the first reference current corresponding to the first reference potential VPR. This means that the current IREF[i+1] flowing in the memory cell MCR[i+1] corresponds to the first reference current, in this case.

The memory cell MCR has a function of holding the first reference potential VPR. In other words, the memory cell MCR has a function of holding the first reference current corresponding to the first reference potential VPR.

Moreover, the second analog potential is input to the memory cell MCR through the wiring RW such as the wiring RW[i] and the wiring RW[i+1]. The memory cell MCR has a function of adding the second analog potential or a potential corresponding to the second analog potential to the first reference potential VPR that is held and a function of holding a second reference potential obtained by the addition. The memory cell MCR also has a function of generating a second reference current corresponding to the second reference potential. In other words, the memory cell MCR has a function of holding the second reference current corresponding to the second reference potential.

Specifically, in the semiconductor device 100 illustrated in FIG. 7, the second analog potential Vw[i,j] is input to the memory cell MCR[i] through the wiring RW[i]. The memory cell MCR[i] has a function of holding a second reference potential corresponding to the first reference potential VPR and the second analog potential Vw[i,j]. The memory cell MCR[i] also has a function of generating the second reference current corresponding to the second reference potential. This means that the current IREF[i] flowing in the memory cell MCR[i] corresponds to the second reference current, in this case.

Furthermore, in the semiconductor device 100 illustrated in FIG. 7, the second analog potential Vw[i+1,j] is input to the memory cell MCR[i+1] through the wiring RW[i+1]. The memory cell MCR[i+1] has a function of holding the first reference potential VPR and a second reference potential corresponding to the second analog potential Vw[i+1,j]. The memory cell MCR[i+1] also has a function of generating the second reference current corresponding to the second reference potential. This means that the current IREF[i+1] flowing in the memory cell MCR[i+1] corresponds to the second reference current, in this case.

The current IREF[i] flows between a wiring BLREF and a wiring VRREF through the memory cell MCR[i]. The current IREF[i+1] flows between the wiring BLREF and the wiring VRREF through the memory cell MCR[i+1]. Accordingly, a current IREF, which corresponds to the sum of the current IREF[i] and the current IREF[i+1], flows between the wiring BLREF and the wiring VRREF through the memory cell MCR[i] and the memory cell MCR[i+1].

The current supply circuit 150 has a function of supplying current with the same value as the current IREF that flows through the wiring BLREF or supplying current corresponding to the current IREF to the wiring BL. In the case where the current I[j] that flows between the wiring BL[j] and the wiring VR[j] through the memory cell MC[i,j] and the memory cell MC[i+1,j] is different from the current IREF that flows between the wiring BLREF and the wiring VRREF through the memory cell MCR[i] and the memory cell MCR[i+1] and thus offset current is set as described later, current corresponding to the difference flows in the circuit 130 or the circuit 140. The circuit 130 serves as a current source circuit, and the circuit 140 serves as a current sink circuit.

Specifically, in the case where the current I[j] is higher than the current IREF, the circuit 130 has a function of generating a current ΔI[j] that corresponds to the difference between the current I[j] and the current IREF. The circuit 130 also has a function of supplying the generated current ΔI[j] to the wiring BL[j]. This means that the circuit 130 has a function of holding the current ΔI[j].

In the case where the current I[j] is lower than the current IREF, the circuit 140 has a function of generating current corresponding to the absolute value of the current ΔI[j] that corresponds the difference between the current I[j] and the current IREF. The circuit 140 also has a function of drawing the generated current ΔI[j] from the wiring BL[j]. This means that the circuit 140 has a function of holding the current ΔI[j].

Next, an operation example of the semiconductor device 100 illustrated in FIG. 7 will be described.

First, a potential corresponding to the first analog potential is stored in the memory cell MC[i,j]. Specifically, a potential VPR−Vx[i,j], which is obtained by subtracting the first analog potential Vx[i,j] from the first reference potential VPR, is input to the memory cell MC[i,j] through the wiring WD[j]. The memory cell MC[i,j] holds the potential VPR−Vx[i,j]. In addition, the memory cell MC[i,j] generates the current I[i,j] that corresponds to the potential VPR−Vx[i,j]. The first reference potential VPR is, for example, a potential that is higher than a ground potential. Specifically, the first reference potential VPR is desirably higher than a ground potential and as high as or lower than a high-level potential VDD that is supplied to the current supply circuit 150.

Furthermore, the first reference potential VPR is stored in the memory cell MCR[i]. Specifically, the first reference potential VPR is input to the memory cell MCR[i] through the wiring WDREF. The memory cell MCR[i] holds the first reference potential VPR. In addition, the memory cell MCR[i] generates the current IREF[i] that corresponds to the first reference potential VPR.

Moreover, a potential corresponding to the first analog potential is stored in the memory cell MC[i+1,j]. Specifically, a potential VPR−Vx[i+1,j], which is obtained by subtracting the first analog potential Vx[i+1,j] from the first reference potential VPR, is input to the memory cell MC[i+1,j] through the wiring WD[j]. The memory cell MC[i+1,j] holds the potential VPR−Vx[i+1,j]. In addition, the memory cell MC[i+1,j] generates the current I[i+1,j] that corresponds to the potential VPR−Vx[i+1,j].

Furthermore, the first reference potential VPR is stored in the memory cell MCR[i+1]. Specifically, the first reference potential VPR is input to the memory cell MCR[i+1] through the wiring WDREF. The memory cell MCR[i+1] holds the first reference potential VPR. In addition, the memory cell MCR[i+1] generates the current IREF[i+1] that corresponds to the first reference potential VPR.

During the above operation, the wiring RW[i] and the wiring RW[i+1] are each set to a base potential. As a base potential, for example, a ground potential or a low-level potential VSS that is lower than a base potential can be used. Alternatively, a potential between the potential VSS and the potential VDD may be used as a base potential. This is preferable because the potential of the wiring RW can be higher than the base potential regardless of whether the second analog potential Vw is positive or negative, which enables easy generation of signals and multiplication of either positive or negative analog data.

As a result of the above operation, current corresponding to the sum of currents generated in the memory cells MC connected to the wiring BL[j] flows through the wiring BL[j]. Specifically, in FIG. 7, the current I[j], which is the sum of the current I[i,j] generated in the memory cell MC[i,j] and the current I[i+1,j] generated in the memory cell MC[i+1,j], flows through the wiring BL[j]. In addition, as a result of the above operation, current corresponding to the sum of currents generated in the memory cells MCR connected to the wiring BLREF flows through the wiring BLREF. Specifically, in FIG. 7, the current IREF, which is the sum of the current IREF[i] generated in the memory cell MCR[i] and the current IREF[i+1] generated in the memory cell MCR[i+1], flows through the wiring BLREF.

Next, an offset current Ioffset[j], which is the difference between the current I[j] obtained by inputting the first analog potential and the current IREF obtained by inputting the first reference potential, is held in the circuit 130 or the circuit 140 while the wiring RW[i] and the wiring RW[i+1] are kept at base potentials.

Specifically, when the current I[j] is higher than the current IREF, the circuit 130 supplies the current Ioffset[j] to the wiring BL[j]. This means that a current ICM[j] that flows in the circuit 130 corresponds to the current Ioffset[j]. The current ICM[j] is held in the circuit 130. When the current I[j] is lower than the current IREF, the circuit 140 draws the current Ioffset[j] from the wiring BL[j]. This means that a current ICP[j] that flows in the circuit 140 corresponds to the current Ioffset[j]. The current ICP[j] is held in the circuit 140.

Then, the second analog potential or a potential corresponding to the second analog potential is stored in the memory cell MC[i,j] so as to be added to the first analog potential or a potential corresponding to the first analog potential held in the memory cell MC[i,j]. Specifically, when the potential of the wiring RW[i] is set to a potential that is higher than a base potential by Vw[i], a second analog potential Vw[i] is input to the memory cell MC[i,j] through the wiring RW[i]. The memory cell MC[i,j] holds a potential VPR−Vx[i,j]+Vw[i]. Furthermore, the memory cell MC[i,j] generates the current I[i,j] corresponding to the potential VPR−Vx[i,j]+Vw[i].

In addition, the second analog potential or the potential corresponding to the second analog potential is stored in the memory cell MC[i+1,j] so as to be added to the first analog potential or a potential corresponding to the first analog potential held in the memory cell MC[i+1,j]. Specifically, when the potential of the wiring RW[i+1] is set to a potential that is higher than a base potential by Vw[i+1], a second analog potential Vw[i+1] is input to the memory cell MC[i+1,j] through the wiring RW[i+1]. The memory cell MC[i+1,j] holds a potential VPR−Vx[i+1,j]+Vw[i+1]. Furthermore, the memory cell MC[i+1,j] generates the current I[i+1,j] corresponding to the potential VPR−Vx[i+1,j]+Vw[i+1].

In the case where the transistor Tr11 that operates in a saturation region is used as an element for converting a potential into current, since the drain current of the transistor Tr11 included in the memory cell MC[i,j] corresponds to the current I[i,j], the second analog current is expressed by Formula 1 below. Note that Vw[i] is the potential of the wiring RW[i], Vw[i+1] is the potential of the wiring RW[i+1], k is a coefficient, and Vth is the threshold voltage of the transistor Tr11.

I[i,j]=k(Vw[i]−Vth+VPR−Vx[i,j])² (Formula 1)

Furthermore, since the drain current of the transistor Tr11 included in the memory cell MCR[i] corresponds to the current IREF[i], the second reference current is expressed by Formula 2 below.

IREF[i]=k(Vw[i]−Vth+VPR)² (Formula 2)

The current I[j], which corresponds to the sum of the current I[i,j] flowing in the memory cell MC[i,j] and the current I[i+1,j] flowing in the memory cell MC[i+1,j], can be expressed as ΣiI[i,j]. The current IREF, which corresponds to the sum of the current IREF[i] flowing in the memory cell MCR[i] and the current IREF[i+1] flowing in the memory cell MCR[i+1], can be expressed as ΣiIREF[i]. Accordingly, the current ΔI[j] that correspond to the difference between the current I[j] and the current IREF is expressed by Formula 3 below.

ΔI[j]=IREF−I[j]=ΣiIREF[i]−ΣiI[i,j] (Formula 3)

The current ΔI[j] can be obtained from Formulae 1 to 3, as expressed by Formula 4 below.

$$Δ I [ j ] = Σ i \{ {k ( Vw [ i ] - Vth + VPR )}^{2} - {k ( Vw [ i ] - Vth + VPR - Vx [ i , j ] )}^{2} \} = 2 k Σ i ( Vw [ i ] \cdot Vx [ i , j ] \} - 2 k Σ i ( Vth - VPR ) \cdot Vx [ i , j ] - k Σ {iVx [ i , j ]}^{2} \qquad ( Formula 4 )$$

The term 2kΣi(Vw[i]·Vx[i,j]) in Formula 4 corresponds to the sum of the product of the first analog potential Vx[i,j] and the second analog potential Vw[i] and the product of the first analog potential Vx[i+1,j] and the second analog potential Vw[i+1].

Furthermore, if the current Ioffset[j] is defined as the current ΔI[j] at the time when the potential of the wiring RW[i] is all set to a base potential, that is, when the second analog potential Vw[i] and the second analog potential Vw[i+1] are both 0, Formula 5 below can be obtained from Formula 4.

Ioffset[j]=−2kΣi(Vth−VPR)·Vx[i,j]−kΣiVx[i,j]² (Formula 5)

It is found from Formulae 3 to 5 that 2kΣi(Vw[i]·Vx[i,j]) that corresponds to the product-sum of the first analog data and the second analog data is expressed by Formula 6 below.

2kΣi(Vw[i]·Vx[i,j])=IREF−I[j]−Ioffset[j] (Formula 6)

When the potential of the wiring RW[i] is Vw[i] and the potential of the wiring RW[i+1] is Vw[i+1], a current Iout[j] that flows from the wiring BL[j] is expressed by IREF−I[j]−Ioffset[j], where I[j] is the sum of currents flowing in the memory cells MC, IREF is the sum of currents flowing in the memory cells MCR, and Ioffset[j] is current flowing in the circuit 130 or the circuit 140. According to Formula 6, the current Iout[j] equals to 2kΣi(Vw[i]·Vx[i,j]), which corresponds to the sum of the product of the first analog potential Vx[i,j] and the second analog potential Vw[i] and the product of the first analog potential Vx[i+1,j] and the second analog potential Vw[i+1].

The transistor Tr11 desirably operates in a saturation region. However, even if the operation region of the transistor Tr11 deviates from an ideal saturation region, the transistor Tr11 is regarded as operating in a saturation region as long as there is no problem in obtaining current that corresponds to the sum of the product of the first analog potential Vx[i,j] and the second analog potential Vw[i] and the product of the first analog potential Vx[i+1,j] and the second analog potential Vw[i+1] with an accuracy within a desired range.

According to one embodiment of the present invention, analog data can be subjected to arithmetic processing without being converted into digital data; thus, the circuit scale of a semiconductor device can be reduced or the time required for the arithmetic processing of analog data can be shortened. Alternatively, according to one embodiment of the present invention, power consumption of a semiconductor device can be reduced while the time required for arithmetic processing of analog data is shortened.

### Configuration Example of Memory Circuit

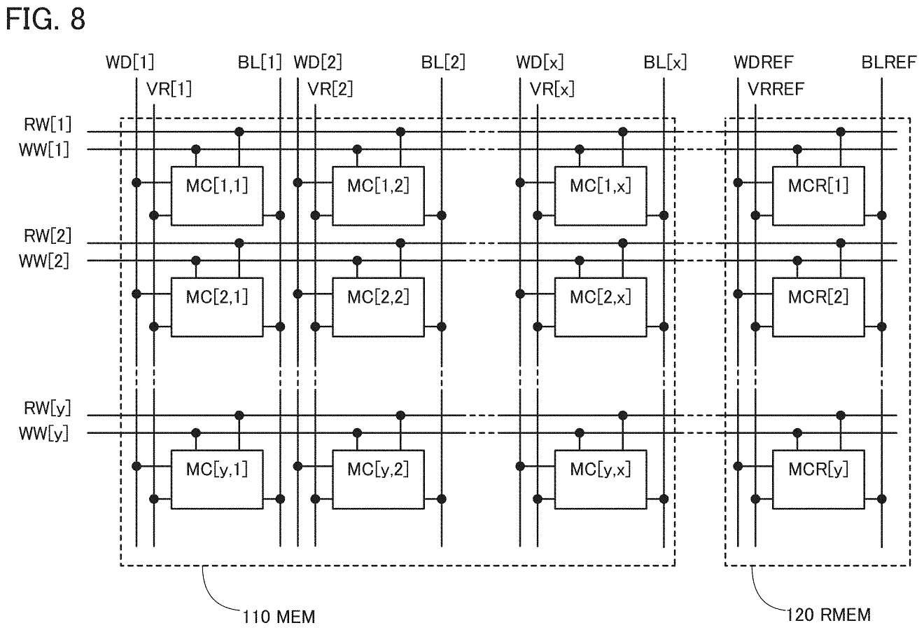

Next, a specific configuration example of the memory circuit 110 (MEM) and the reference memory circuit 120 (RMEM) will be described with reference to FIG. 8.

FIG. 8 illustrates an example where the memory circuit 110 (MEM) includes the memory cells MC in y rows and x columns (x and y are natural numbers) and the reference memory circuit 120 (RMEM) includes the memory cells MCR in y rows and one column.

The memory circuit 110 is connected to the wiring RW, a wiring WW, the wiring WD, the wiring VR, and the wiring BL. In the example illustrated in FIG. 8, wirings RW[1] to RW[y] and wirings WW[1] to WW[y] are connected to the memory cells MC in the respective rows. Moreover, wirings WD[1] to WD[x], wirings BL[1] to BL[x], and wirings VR[1] to VR[x] are connected to the memory cells MC in the respective columns. Note that the wirings VR[1] to VR[x] may be connected to each other.

The reference memory circuit 120 is connected to the wiring RW, the wiring WW, the wiring WDREF, the wiring VRREF, and the wiring BLREF. In the example illustrated in FIG. 8, the wirings RW[1] to RW[y] and the wirings WW[1] to WW[y] are connected to the memory cells MCR in the respective rows. Moreover, the wiring WDREF, the wiring BLREF, and the wiring VRREF are connected to the memory cells MCR in the one column. Note that the wiring VRREF may be connected to the wirings VR[1] to VR[x].

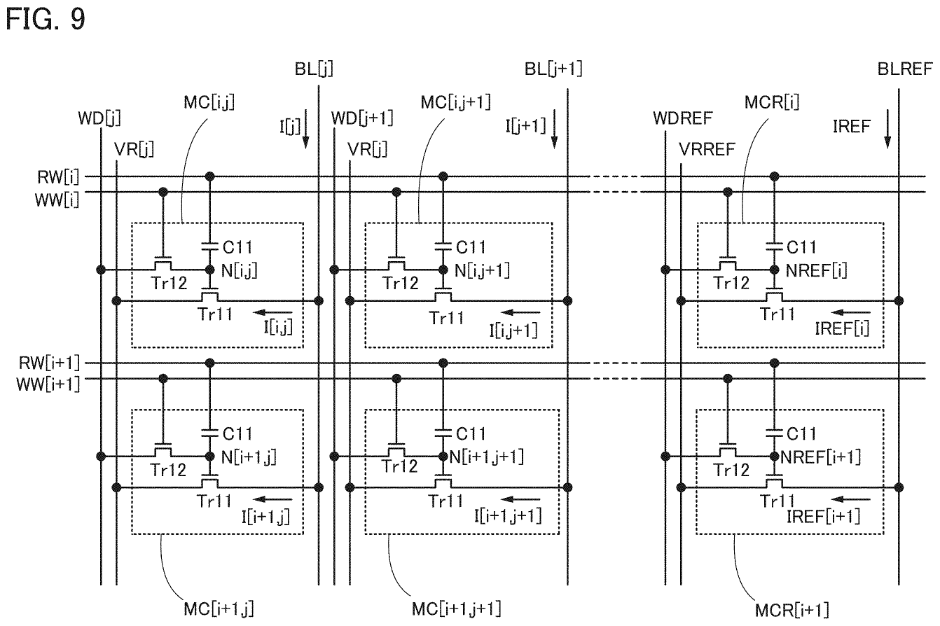

FIG. 9 illustrates, as an example, a specific circuit configuration and a specific connection relationship of the memory cells MC in any two rows and two columns among the memory cells MC illustrated in FIG. 8 and the memory cells MCR in any two rows and one column among the memory cells MCR illustrated in FIG. 8.

Specifically, FIG. 9 illustrates the memory cell MC[i,j] in the i-th row and the j-th column, the memory cell MC[i+1,j] in the i+1-th row and the j-th column, a memory cell MC[i,j+1] in the i-th row and the j+1-th column, and a memory cell MC[i+1,j+1] in the i+1-th row and the j+1-th column. FIG. 9 also illustrates the memory cell MCR[i] in the i-th row and the memory cell MCR[i+1] in the i+1-th row. Note that i and i+1 are each any number from 1 to y, and j and j+1 are each any number from 1 to x.

The memory cell MC[i,j], the memory cell MC[i,j+1], and the memory cell MCR[i] in the i-th row are connected to the wiring RW[i] and a wiring WW[i]. The memory cell MC[i+1,j], the memory cell MC[i+1,j+1], and the memory cell MCR[i+1] in the i+1-th row are connected to the wiring RW[i+1] and a wiring WW[i+1].

The memory cell MC[i,j] and the memory cell MC[i+1,j] in the j-th column are connected to the wiring WD[j], the wiring VR[j], and the wiring BL[j]. The memory cell MC[i,j+1] and the memory cell MC[i+1,j+1] in the j+1-th column are connected to a wiring WD[j+1], a wiring VR[j+1], and a wiring BL[j+1]. The memory cell MCR[i] in the i-th row and the memory cell MCR[i+1] in the i+1-th row are connected to the wiring WDREF, the wiring VRREF, and the wiring BLREF.

The memory cells MC and MCR each include the transistor Tr11, a transistor Tr12, and a capacitor C11. The transistor Tr12 has a function of controlling the input of the first analog potential to the memory cell MC or the memory cell MCR. The transistor Tr11 has a function of generating analog current in accordance with a potential input to its gate. The capacitor C11 has a function of adding the second analog potential or a potential corresponding to the second analog potential to the first analog potential or a potential corresponding to the first analog potential that is held in the memory cell MC or the memory cell MCR.

Specifically, in the memory cell MC illustrated in FIG. 9, a gate of the transistor Tr12 is connected to the wiring WW, one of a source and a drain of the transistor Tr12 is connected to the wiring WD, and the other of the source and the drain of the transistor Tr12 is connected to the gate of the transistor Tr11. Furthermore, one of a source and a drain of the transistor Tr11 is connected to the wiring VR, and the other of the source and the drain of the transistor Tr11 is connected to the wiring BL. A first electrode of the capacitor C11 is connected to the wiring RW, and a second electrode of the capacitor C11 is connected to the gate of the transistor Tr11.

In addition, in the memory cell MCR illustrated in FIG. 9, a gate of the transistor Tr12 is connected to the wiring WW, one of a source and a drain of the transistor Tr12 is connected to the wiring WDREF, and the other of the source and the drain of the transistor Tr12 is connected to the gate of the transistor Tr11. Furthermore, one of a source and a drain of the transistor Tr11 is connected to the wiring VRREF, and the other of the source and the drain of the transistor Tr11 is connected to the wiring BLREF. A first electrode of the capacitor C11 is connected to the wiring RW, and a second electrode of the capacitor C11 is connected to the gate of the transistor Tr11.

The gate of the transistor Tr11 in the memory cell MC is called a node N here. In the memory cell MC, the first analog potential or a potential corresponding to the first analog potential is input to the node N through the transistor Tr12. Then, when the transistor Tr12 is turned off, the node N is brought into a floating state and the first analog potential or the potential corresponding to the first analog potential is held at the node N. In the memory cell MC, when the node N is brought into a floating state, the second analog potential or a potential corresponding to the second analog potential input to the first electrode of the capacitor C11 is applied to the node N. As a result of the above operation, the node N can have a potential obtained by adding the second analog potential or the potential corresponding to the second analog potential to the first analog potential or the potential corresponding to the first analog potential.

Because the potential of the first electrode of the capacitor C11 is applied to the node N through the capacitor C11, the amount of change in the potential of the first electrode is not exactly the same as the amount of change in the potential of the node N, actually. Specifically, the accurate amount of change in the potential of the node N can be calculated in the following manner: a coupling coefficient uniquely determined by the capacitance value of the capacitor C11, the value of the gate capacitance of the transistor Tr11, and the value of parasitic capacitance is multiplied by the amount of change in the potential of the first electrode. In the following description, the amount of change in the potential of the first electrode is assumed to be substantially the same as the amount of change in the potential of the node N, for easy understanding.

The drain current of the transistor Tr11 is determined in accordance with the potential of the node N. Thus, when the transistor Tr12 is turned off, the value of the drain current of the transistor Tr11 as well as the potential of the node N is held. The drain current is affected by the first analog potential and the second analog potential.

The gate of the transistor Tr11 in the memory cell MCR is called a node NREF here. In the memory cell MCR, the first reference potential or a potential corresponding to the first reference potential is input to the node NREF through the transistor Tr12. Then, when the transistor Tr12 is turned off, the node NREF is brought into a floating state and the first reference potential or the potential corresponding to the first reference potential is held at the node NREF. In the memory cell MCR, when the node NREF is brought into a floating state, the second analog potential or a potential corresponding to the second analog potential input to the first electrode of the capacitor C11 is applied to the node NREF. As a result of the above operation, the node NREF can have a potential obtained by adding the second analog potential or the potential corresponding to the second analog potential to the first reference potential or the potential corresponding to the first reference potential.

The drain current of the transistor Tr11 is determined in accordance with the potential of the node NREF. Thus, when the transistor Tr12 is turned off, the value the drain current of the transistor Tr11 as well as the potential of the node NREF is held. The drain current is affected by the first reference potential and the second analog potential.

When the drain current of the transistor Tr11 in the memory cell MC[i,j] is the current I[i,j] and the drain current of the transistor Tr11 in the memory cell MC[i+1,j] is the current I[i+1,j], the sum of currents supplied to the memory cell MC[i,j] and the memory cell MC[i+1,j] through the wiring BL[j] is the current I[j]. When the drain current of the transistor Tr11 in the memory cell MC[i,j+1] is a current I[i,j+1] and the drain current of the transistor Tr11 in the memory cell MC[i+1,j+1] is a current I[i+1,j+1], the sum of currents supplied to the memory cell MC[i,j+1] and the memory cell MC[i+1,j+1] through the wiring BL[j+1] is a current I[j+1]. When the drain current of the transistor Tr11 in the memory cell MCR[i] is the current IREF[i] and the drain current of the transistor Tr11 in the memory cell MCR[i+1] is the current IREF[i+1], the sum of currents supplied to the memory cell MCR[i] and the memory cell MCR[i+1] through the wiring BLREF is the current IREF.

### Configuration Example of Circuit 130, Circuit 140, and Current Supply Circuit

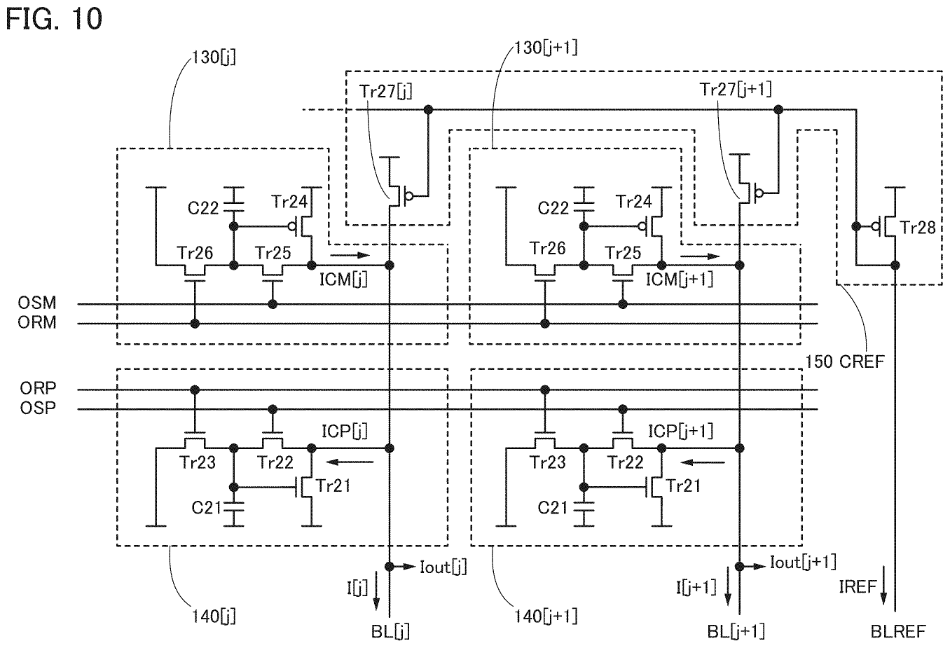

Then, a specific configuration example of the circuit 130, the circuit 140, and the current supply circuit 150 (CREF) will be described with reference to FIG. 10.

FIG. 10 illustrates a configuration example of the circuit 130, the circuit 140, and the current supply circuit 150 for the memory cell MC and the memory cell MCR illustrated in FIG. 9. Specifically, FIG. 10 illustrates a circuit 130[j] for the memory cells MC in the j-th column and a circuit 130[j+1] the memory cells MC in the j+1-th column, as the circuit 130. FIG. 10 illustrates a circuit 140[j] for the memory cells MC in the j-th column and a circuit 140[j+1] for the memory cells MC in the j+1-th column, as the circuit 140.

The circuit 130[j] and the circuit 140[j] are connected to the wiring BL[j]. The circuit 130[j+1] and the circuit 140[j+1] are connected to the wiring BL[j+1].

The current supply circuit 150 is connected to the wiring BL[j], the wiring BL[j+1], and the wiring BLREF. The current supply circuit 150 has a function of supplying the current IREF to the wiring BLREF and a function of supplying current that is the same as the current IREF or current that corresponds to the current IREF to each of the wiring BL[j] and the wiring B[j+1].

Specifically, the circuit 130[j] and the circuit 130[j+1] each include a transistor Tr24, a transistor Tr25, a transistor Tr26, and a capacitor C22. The transistor Tr24 in the circuit 130[j] has a function of generating the current ICM[j] that corresponds to the difference between the current I[j] and the current IREF, when the current I[j] is higher than the current IREF and offset current is set. Furthermore, the transistor Tr24 in the circuit 130[j] has a function of generating a current ICM[j+1] that corresponds to the difference between the current I[j+1] and the current IREF, when the current I[j+1] is higher than the current IREF. The current ICM[j] and the current ICM[j+1] are supplied from the circuit 130[j] and the circuit 130[j+1] to the wiring BL[j] and the wiring BL[j+1], respectively.

In each of the circuit 130[j] and the circuit 130[j+1], one of a source and a drain of the transistor Tr24 is connected to the corresponding wiring BL, and the other of the source and the drain is connected to a wiring through which a predetermined potential is supplied. One of a source and a drain of the transistor Tr25 is connected to the corresponding wiring BL, and the other of the source and the drain is connected to a gate of the transistor Tr24. One of a source and a drain of the transistor Tr26 is connected to the gate of the transistor Tr24, and the other of the source and the drain is connected to a wiring through which a predetermined potential is supplied. A first electrode of the capacitor C22 is connected to the gate of the transistor Tr24, and a second electrode of the capacitor C22 is connected to a wiring through which a predetermined potential is supplied.

A gate of the transistor Tr25 is connected to a wiring OSM, and a gate of the transistor Tr26 is connected to a wiring ORM.

Note that FIG. 10 illustrates an example where the transistor Tr24 is a p-channel transistor and the transistors Tr25 and Tr26 are n-channel transistors.

The circuit 140[j] and the circuit 140[j+1] each include a transistor Tr21, a transistor Tr22, a transistor Tr23, and a capacitor C21. The transistor Tr21 in the circuit 140[j] has a function of generating the current ICP[j] that corresponds to the difference between the current I[j] and the current IREF, when the current I[j] is lower than the current IREF and offset current is set. Furthermore, the transistor Tr21 in the circuit 140[j+1] has a function of generating a current ICP[j+1] that corresponds to the difference between the current I[j+1] and the current IREF, when the current I[j+1] is lower than the current IREF. The current ICP[j] and the current ICP[j+1] are drawn from the wiring BL[j] and the wiring BL[j+1] into the circuit 140[j] and the circuit 140[j+1], respectively.

Note that the current ICM[j] and the current ICP[j] each correspond to the current Ioffset[j], and the current ICM[j+1] and the current ICP[j+1] each correspond to a current Ioffset[j+1].

In each of the circuit 140[j] and the circuit 140[j+1], one of a source and a drain of the transistor Tr21 is connected to the corresponding wiring BL, and the other of the source and the drain is connected to a wiring through which a predetermined potential is supplied. One of a source and a drain of the transistor Tr22 is connected to the corresponding wiring BL, and the other of the source and the drain is connected to a gate of the transistor Tr21. One of a source and a drain of the transistor Tr23 is connected to the gate of the transistor Tr21, and the other of the source and the drain is connected to a wiring through which a predetermined potential is supplied. A first electrode of the capacitor C21 is connected to the gate of the transistor Tr21, and a second electrode of the capacitor C21 is connected to a wiring through which a predetermined potential is supplied.

A gate of the transistor Tr22 is connected to a wiring OSP, and a gate of the transistor Tr23 is connected to a wiring ORP.

Note that FIG. 10 illustrates an example where the transistors Tr21 to Tr23 are n-channel transistors.

The current supply circuit 150 includes a transistor Tr27 for the wiring BL and a transistor Tr28 for the wiring BLREF. Specifically, FIG. 10 illustrates an example where the current supply circuit 150 includes, as the transistor Tr27, a transistor Tr27[j] for the wiring BL[j] and a transistor Tr27[j+1] for the wiring BL[j+1].

A gate of the transistor Tr27 is connected to a gate of the transistor Tr28. One of a source and a drain of the transistor Tr27 is connected to the corresponding wiring BL, and the other of the source and the drain is connected to a wiring through which a predetermined potential is supplied. One of a source and a drain of the transistor Tr28 is connected to the wiring BLREF, and the other of the source and the drain is connected to a wiring through which a predetermined potential is supplied.

The transistors Tr27 and Tr28 have the same polarity. FIG. 10 illustrates an example where the transistors Tr27 and Tr28 are p-channel transistors.

The drain current of the transistor Tr28 corresponds to the current IREF. The transistor Tr27 and the transistor Tr28 collectively serve as a current mirror circuit; thus, the drain current of the transistor Tr27 is substantially the same as the drain current of the transistor Tr28 or corresponds to the drain current of the transistor Tr28.

### Operation Example of Semiconductor Device

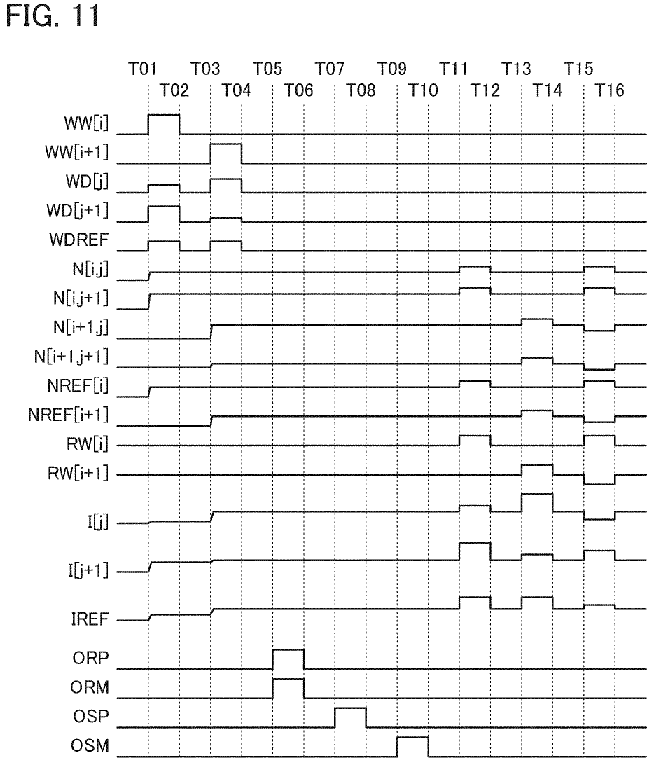

Next, a specific operation example of the semiconductor device 100 of one embodiment of the present invention will be described with reference to FIG. 9, FIG. 10, and FIG. 11.

FIG. 11 is an example of a timing chart showing the operations of the memory cell MC and the memory cell MCR illustrated in FIG. 9 and the circuit 130, the circuit 140, and the current supply circuit 150 illustrated in FIG. 10. From Time T01 to Time T04 in FIG. 11, the first analog data is stored in the memory cell MC and the memory cell MCR. From Time T05 to Time T10, the value of the offset current Ioffset that is supplied from the circuit 130 and the circuit 140 is set. From Time T11 to Time T16, data corresponding to the product-sum of the first analog data and the second analog data is acquired.

Note that a low-level potential VSS is supplied to the wiring VR[j] and the wiring VR[j+1]. The high-level potential VDD is supplied to all wirings having a predetermined potential that are connected to the circuit 130. The low-level potential VSS is supplied to all wirings having a predetermined potential that are connected to the circuit 140. Furthermore, the high-level potential VDD is supplied to all wirings having a predetermined potential that are connected to the current supply circuit 150.

The transistors Tr11, Tr21, Tr24, Tr27[j], Tr27[j+1], and Tr28 each operate in a saturation region.

First, a high-level potential is applied to the wiring WW[i] and a low-level potential is applied to the wiring WW[i+1] from Time T01 to Time T02. Accordingly, the transistors Tr12 in the memory cell MC[i,j], the memory cell MC[i,j+1], and the memory cell MCR[i] illustrated in FIG. 9 are turned on. The transistors Tr12 in the memory cell MC[i+1,j], the memory cell MC[i+1,j+1], and the memory cell MCR[i+1] remain off

In addition, from Time T01 to Time T02, a potential obtained by subtracting the first analog potential from the first reference potential VPR is applied to each of the wiring WD[j] and the wiring WD[j+1] illustrated in FIG. 9. Specifically, the potential VPR−Vx[i,j] is applied to the wiring WD[j], and a potential VPR−Vx[i,j+1] is applied to the wiring WD[j+1]. The first reference potential VPR is applied to the wiring WDREF, and a potential between the potential VSS and the potential VDD, e.g., a potential (VDD+VSS)/2, is applied as a base potential to the wiring RW[i] and the wiring RW[i+1].

Accordingly, the potential VPR−Vx[i,j] is applied to a node N[i,j] through the transistor Tr12 in the memory cell MC[i,j] illustrated in FIG. 9, the potential VPR−Vx[i,j+1] is applied to a node N[i,j+1] through the transistor Tr12 in the memory cell MC[i,j+1], and the first reference potential VPR is applied to a node NREF[i] through the transistor Tr12 in the memory cell MCR[i].

After Time T02, the potential applied to the wiring WW[i] illustrated in FIG. 9 changes from a high-level potential to a low-level potential, so that the transistors Tr12 in the memory cell MC[i,j], the memory cell MC[i,j+1], and the memory cell MCR[i] are turned off. Accordingly, the potential VPR−Vx[i,j] is held at the node N[i,j], the potential VPR−Vx[i,j+1] is held at the node N[i,j+1], and the first reference potential VPR is held at the node NREF[i].

Then, from Time T03 to Time T04, the potential of the wiring WW[i] illustrated in FIG. 9 remains at a low level and a high-level potential is applied to the wiring WW[i+1]. Accordingly, the transistors Tr12 in the memory cell MC[i+1,j], the memory cell MC[i+1,j+1], and the memory cell MCR[i+1] illustrated in FIG. 9 are turned on. The transistors Tr12 in the memory cell MC[i,j], the memory cell MC[i,j+1], and the memory cell MCR[i] remain off

In addition, from Time T03 to Time T04, a potential obtained by subtracting the first analog potential from the first reference potential VPR is applied to each of the wiring WD[j] and the wiring WD[j+1] illustrated in FIG. 9. Specifically, the potential VPR−Vx[i+1,j] is applied to the wiring WD[j], and a potential VPR−Vx[i+1,j+1] is applied to the wiring WD[j+1]. The first reference potential VPR is applied to the wiring WDREF, and a potential between the potential VSS and the potential VDD, e.g., the potential (VDD+VSS)/2, is applied as a base potential to the wiring RW[i] and the wiring RW[i+1].

Accordingly, the potential VPR−Vx[i+1,j] is applied to a node N[i+1,j] through the transistor Tr12 in the memory cell MC[i+1,j] illustrated in FIG. 9, the potential VPR−Vx[i+1,j+1] is applied to a node N[i+1,j+1] through the transistor Tr12 in the memory cell MC[i+1,j+1], and the first reference potential VPR is applied to a node NREF[i+1] through the transistor T12 in the memory cell MCR[i+1].

After Time T04, the potential applied to the wiring WW[i+1] illustrated in FIG. 9 changes from a high-level potential to a low-level potential, so that the transistors Tr12 in the memory cell MC[i+1,j], the memory cell MC[i+1,j+1], and the memory cell MCR[i+1] are turned off. Accordingly, the potential VPR−Vx[i+1,j] is held at the node N[i+1,j], the potential VPR−Vx[i+1,j+1] is held at the node N[i+1,j+1], and the first reference potential VPR is held at the node NREF[i+1].

Next, a high-level potential is applied to the wiring ORP and the wiring ORM illustrated in FIG. 10 from Time T05 to Time T06. When a high-level potential is applied to the wiring ORM, the transistors Tr26 in the circuit 130[j] and the circuit 130[j+1] illustrated in FIG. 10 are turned on, so that the gates of the transistors Tr24 are reset by the potential VDD applied thereto. Furthermore, when a high-level potential is applied to the wiring ORP, the transistors Tr23 in the circuit 140[j] and the circuit 140[j+1] illustrated in FIG. 10 are turned on, so that the gates of the transistors Tr21 are reset by the potential VSS applied thereto.

After Time T06, the potential applied to the wiring ORP and the wiring ORM illustrated in FIG. 10 changes from a high-level potential to a low-level potential, so that the transistors Tr26 in the circuit 130[j] and the circuit 130[j+1] and the transistors Tr23 in the circuit 140[j] and the circuit 140[j+1] are turned off. Accordingly, the potential VDD is held at the gate of the transistor Tr24 in each of the circuit 130[j] and the circuit 130[j+1], and the potential VSS is held at the gate of the transistor Tr21 in each of the circuit 140[j] and the circuit 140[j+1].

From Time T07 to Time T08, a high-level potential is applied to the wiring OSP illustrated in FIG. 10. Furthermore, a potential between the potential VSS and the potential VDD, e.g., the potential (VDD+VSS)/2, is applied as a base potential to the wiring RW[i] and the wiring RW[i+1] illustrated in FIG. 9. Since a high-level potential is applied to the wiring OSP, the transistors Tr22 in the circuit 140[j] and the circuit 140[j+1] are turned on.

If the current I[j] flowing through the wiring BL[j] is lower than the current IREF flowing through the wiring BLREF, that is, if the current ΔI[j] has a positive value, it means that the sum of current that can be drawn by the transistor Tr28 in the memory cell MC[i,j] illustrated in FIG. 9 and current that can be drawn by the transistor Tr28 in the memory cell MC[i+1,j] is smaller than the value of the drain current of the transistor Tr27[j]. Thus, if the current ΔI[j] has a positive value, part of the drain current of the transistor Tr27[j] flows to the gate of the transistor Tr21 when the transistor Tr22 is turned on in the circuit 140[j], and the potential of the gate starts to rise. When the drain current of the transistor Tr21 becomes substantially equal to the current ΔI[j], the potential of the gate of the transistor Tr21 converges on a certain value. The potential of the gate of the transistor Tr21 at this time corresponds to a potential at which the drain current of the transistor Tr21 becomes the current ΔI[j], i.e., the current Ioffset[j] (=ICP[j]). This means that the transistor Tr21 in the circuit 140[j] is in a state of serving as a current source that can supply the current ICP[j].

Similarly, if the current I[j+1] flowing through the wiring BL[j+1] is lower than the current IREF flowing through the wiring BLREF, that is, if a current ΔI[j+1] has a positive value, part of the drain current of the transistor Tr27[j+1] flows to the gate of the transistor Tr21 when the transistor Tr22 is turned on in the circuit 140[j+1], and the potential of the gate starts to rise. When the drain current of the transistor Tr21 becomes substantially equal to the current ΔI[j+1], the potential of the gate of the transistor Tr21 converges on a certain value. The potential of the gate of the transistor Tr21 at this time corresponds to a potential at which the drain current of the transistor Tr21 becomes the current ΔI[j+1], i.e., the current Ioffset[j+1] (=ICP[j+1]). This means that the transistor Tr21 in the circuit 140[j+1] is in a state of serving as a current source that can supply the current ICP[j+1].

After Time T08, the potential applied to the wiring OSP illustrated in FIG. 10 changes from a high-level potential to a low-level potential, so that the transistors Tr22 in the circuit 140[j] and the circuit 140[j+1] are turned off. Accordingly, the potentials of the gates of the transistors Tr21 are held. Thus, the circuit 140[j] remains in a state of serving as the current source that can supply the current ICP[j], and the circuit 140[j+1] remains in a state of serving as the current source that can supply the current ICP[j+1].

From Time T09 to Time T10, a high-level potential is applied to the wiring OSM illustrated in FIG. 10. Furthermore, a potential between the potential VSS and the potential VDD, e.g., the potential (VDD+VSS)/2, is applied as a base potential to each of the wiring RW[i] and the wiring RW[i+1] illustrated in FIG. 9. Since a high-level potential is applied to the wiring OSM, the transistors Tr25 in the circuit 130[j] and the circuit 130[j+1] are turned on.

If the current I[j] flowing through the wiring BL[j] is higher than the current IREF flowing through the wiring BLREF, that is, if the current ΔI[j] has a negative value, it means that the sum of current that can be drawn by the transistor Tr28 in the memory cell MC[i,j] illustrated in FIG. 9 and current that can be drawn by the transistor Tr28 in the memory cell MC[i+1,j] is larger than the value of the drain current of the transistor Tr27[j]. Thus, if the current ΔI[j] has a negative value, current flows from the gate of the transistor Tr24 to the wiring BL[j] when the transistor Tr25 is turned on in the circuit 130[j], and the potential of the gate starts to decrease. When the drain current of the transistor Tr24 becomes substantially equal to the current ΔI[j], the potential of the gate of the transistor Tr24 converges on a certain value. The potential of the gate of the transistor Tr24 at this time corresponds to a potential at which the drain current of the transistor Tr24 becomes the current ΔI[j], i.e., the current Ioffset[j] (=ICM[j]). This means that the transistor Tr24 in the circuit 130[j] is in a state of serving as a current source that can supply the current ICM[j].

Similarly, if the current I[j+1] flowing through the wiring BL[j+1] is higher than the current IREF flowing through the wiring BLREF, that is, if the current ΔI[j+1] has a negative value, current flows from the gate of the transistor Tr24 in the circuit 130[j+1] to the wiring BL[j+1] when the transistor Tr25 is turned on, and the potential of the gate starts to decrease. When the drain current of the transistor Tr24 becomes substantially equal to the absolute value of the current ΔI[j+1], the potential of the gate of the transistor Tr24 converges on a certain value. The potential of the gate of the transistor Tr24 at this time corresponds to a potential at which the drain current of the transistor Tr24 becomes equal to the absolute value of the current ΔI[j+1], i.e., the current Ioffset[j+1] (=ICM[j+1]). This means that the transistor Tr24 in the circuit 130[j+1] is in a state of serving as a current source that can supply the current ICM[j+1].

After Time T10, the potential applied to the wiring OSM illustrated in FIG. 10 changes from a high-level potential to a low-level potential, so that the transistors Tr25 in the circuit 130[j] and the circuit 130[j+1] are turned off. Accordingly, the potentials of the gates of the transistors Tr24 are held. Thus, the circuit 130[j] remains in a state of serving as the current source that can supply the current ICM[j], and the circuit 130[j+1] remains in a state of serving as the current source that can supply the current ICM[j+1].

In each of the circuit 140[j] and the circuit 140[j+1], the transistor Tr21 has a function of drawing current. Thus, from Time T07 to Time T08, when the current I[j] flowing through the wiring BL[j] is higher than the current IREF flowing through the wiring BLREF and the current ΔI[j] has a negative value, or when the current I[j+1] flowing through the wiring BL[j+1] is higher than the current IREF flowing through the wiring BLREF and the current ΔI[j+1] has a negative value, it might be difficult to supply current from the circuit 140[j] or the circuit 140[j+1] to the wiring BL[j] or the wiring BL[j+1] without excess or deficiency. In that case, it might be difficult for the transistor Tr11 in the memory cell MC, the transistor Tr21 in the circuit 140[j+1] or the circuit 140[j+1], and the transistor Tr27[j] or Tr27[j+1] to concurrently operate in a saturation region because a balance between the current flowing through the wiring BLREF and the current flowing through the wiring BL[j] or the wiring BL[j+1] is struck.

To ensure the operations of the transistor Tr11, the transistor Tr21, and the transistor Tr27[j] or Tr27[j+1] in a saturation region from Time T07 to Time T08 even when the current ΔI[j] has a negative value, the potential of the gate of the transistor Tr24 may be set to a potential that is high enough to obtain a predetermined drain current, instead of resetting the potential of the gate of the transistor Tr24 to the potential VDD, from Time T05 to Time T06. In the above configuration, the amount of current that cannot be drawn by the transistor Tr11 can be drawn by the transistor Tr21 to some extent because current from the transistor Tr24, as well as the drain current of the transistor Tr27[j] or Tr27[j+1], is supplied; thus, the operations of the transistor Tr11, the transistor Tr21, and the transistor Tr27[j] or Tr27[j+1] in a saturation region can be ensured.

Note that if the current I[j] flowing through the wiring BL[j] is lower than the current IREF flowing through the wiring BLREF, that is, if the current ΔI[j] has a positive value, from Time T09 to Time T10, since the circuit 140[j] has been set as the current source that can supply the current ICP[j] from Time T07 to Time T08, the potential of the gate of the transistor Tr24 in the circuit 130[j] keeps a value substantially the same as that of the potential VDD. Similarly, if the current I[j+1] flowing through the wiring BL[j+1] is lower than the current IREF flowing through the wiring BLREF, that is, if the current ΔI[j+1] has a positive value, since the circuit 140[j+1] has been set as the current source that can supply the current ICP[j+1] from Time T07 to Time 08, the potential of the gate of the transistor Tr24 in the circuit 130[j+1] keeps a value substantially the same as that of the potential VDD.

Then, from Time T11 to Time T12, the second analog potential Vw[i] is applied to the wiring RW[i] illustrated in FIG. 9. Furthermore, a potential between the potential VSS and the potential VDD, e.g., the potential (VDD+VSS)/2, is still applied as a base potential to the wiring RW[i+1]. In practice, the potential of the wiring RW[i] is a potential higher than the potential between the potential VSS and the potential VDD (e.g., the potential (VDD+VSS)/2), which is a base potential, by Vw[i]; for the simplicity of the following description, however, the potential of the wiring RW[i] is assumed to be the second analog potential Vw[i].

When the potential of the wiring RW[i] becomes the second analog potential Vw[i], with the assumption that the amount of change in the potential of the first electrode of the capacitor C11 is substantially the same as the amount of change in the potential of the node N, the potential of the node N in the memory cell MC[i,j] illustrated in FIG. 9 becomes VPR−Vx[i,j]+Vw[i] and the potential of the node N in the memory cell MC[i,j+1] becomes VPR−Vx[i,j+1]+Vw[i]. According to Formula 6, the product-sum of the first analog data and the second analog data for the memory cell MC[i,j] affects current obtained by subtracting the current Ioffset[j] from the current ΔI[j], that is, the current Iout[j] flowing from the wiring BL[j]. Furthermore, the product-sum of the first analog data and the second analog data for the memory cell MC[i,j+1] affects current obtained by subtracting the current Ioffset[j+1] from the current ΔI[j+1], that is, a current Iout[j+1] flowing from the wiring BL[j+1].

After Time T12, a potential between the potential VSS and the potential VDD (e.g., the potential (VDD+VSS)/2), which is a base potential, is applied again to the wiring RW[i].

Then, from Time T13 to Time T14, the second analog potential Vw[i+1] is applied to the wiring RW[i+1] illustrated in FIG. 9. Furthermore, a potential between the potential VSS and the potential VDD, e.g., the potential (VDD+VSS)/2, is still applied as a base potential to the wiring RW[i]. In practice, the potential of the wiring RW[i+1] is a potential higher than the potential between the potential VSS and the potential VDD (e.g., the potential (VDD+VSS)/2), which is a base potential, by Vw[i+1]; for the simplicity of the following description, however, the potential of the wiring RW[i+1] is assumed to be the second analog potential Vw[i+1].

When the potential of the wiring RW[i+1] becomes the second analog potential Vw[i+1], with the assumption that the amount of change in the potential of the first electrode of the capacitor C11 is substantially the same as the amount of change in the potential of the node N, the potential of the node N in the memory cell MC[i+1,j] illustrated in FIG. 9 becomes VPR−Vx[i+1,j]+Vw[i+1] and the potential of the node N in the memory cell MC[i+1,j+1] becomes VPR−Vx[i+1,j+1]+Vw[i+1]. According to Formula 6, the product-sum of the first analog data and the second analog data for the memory cell MC[i+1,j] affects current obtained by subtracting the current Ioffset[j] from the current ΔI[j], that is, the current Iout[j]. Furthermore, the product-sum of the first analog data and the second analog data for the memory cell MC[i+1,j+1] affects current obtained by subtracting the current Ioffset[j+1] from the current ΔI[j+1], that is, a current Iout[j+1].

After Time T12, a potential between the potential VSS and the potential VDD (e.g., the potential (VDD+VSS)/2), which is a base potential, is applied again to the wiring RW[i+1].

Then, from Time T15 to Time T16, the second analog potential Vw[i] is applied to the wiring RW[i] illustrated in FIG. 9 and the second analog potential Vw[i+1] is applied to the wiring RW[i+1]. In practice, the potential of the wiring RW[i] is a potential higher than the potential between the potential VSS and the potential VDD (e.g., the potential (VDD+VSS)/2), which is a base potential, by Vw[i], and the potential of the wiring RW[i+1] is a potential higher than the potential between the potential VSS and the potential VDD (e.g., the potential (VDD+VSS)/2), which is a base potential, by Vw[i+1]; for the simplicity of the following description, however, the potential of the wiring RW[i] is assumed to be the second analog potential Vw[i] and the potential of the wiring RW[i+1] is assumed to be the second analog potential Vw[i+1].

When the potential of the wiring RW[i] becomes the second analog potential Vw[i], with the assumption that the amount of change in the potential of the first electrode of the capacitor C11 is substantially the same as the amount of change in the potential of the node N, the potential of the node N in the memory cell MC[i,j] illustrated in FIG. 9 becomes VPR−Vx[i,j]+Vw[i] and the potential of the node N in the memory cell MC[i,j+1] becomes VPR−Vx[i,j+1]+Vw[i]. Furthermore, when the potential of the wiring RW[i+1] becomes the second analog potential Vw[i+1], with the assumption that the amount of change in the potential of the first electrode of the capacitor C11 is substantially the same as the amount of change in the potential of the node N, the potential of the node N in the memory cell MC[i+1,j] illustrated in FIG. 9 becomes VPR−Vx[i+1,j]+Vw[i+1] and the potential of the node N in the memory cell MC[i+1,j+1] becomes VPR−Vx[i+1,j+1]+Vw[i+1].

According to Formula 6, the product-sum of the first analog data and the second analog data for the memory cell MC[i,j] and the memory cell MC[i+1,j] affects current obtained by subtracting the current Ioffset[j] from the current ΔI[j], that is, the current Iout[j]. Furthermore, the product-sum of the first analog data and the second analog data for the memory cell MC[i,j+1] and the memory cell MC[i+1,j+1] affects current obtained by subtracting the current Ioffset[j+1] from the current ΔI[j+1], that is, a current Iout[j+1].

After Time T16, a potential between the potential VSS and the potential VDD (e.g., the potential (VDD+VSS)/2), which is a base potential, is applied again to the wiring RW[i] and the wiring RW[i+1].

With the above configuration, the product-sum operation can be performed with a small circuit scale. With the above configuration, the product-sum operation can be performed at high speed. With the above configuration, the product-sum operation can be performed with low power.

Note that a transistor with an extremely low off-state current is desirably used as the transistor Tr12, Tr22, Tr23, Tr25, or Tr26. When a transistor with an extremely low off-state current is used as the transistor Tr12, the potential of the node N can be held for a long time. When a transistor with an extremely low off-state current is used as the transistors Tr22 and Tr23, the potential of the gate of the transistor Tr21 can be held for a long time. When a transistor with an extremely low off-state current is used as the transistors Tr25 and Tr26, the potential of the gate of the transistor Tr24 can be held for a long time.

As a transistor with an extremely low off-state current, an OS transistor may be used. The leakage current of an OS transistor normalized by channel width can be lower than or equal to 10×10⁻²¹ A/μm (10 zA/μm) with a source-drain voltage of 10 V at room temperature (approximately 25° C.).

With the use of the semiconductor device described above, the product-sum operation in the neural network NN1 or the neural network NN2 can be performed.

This embodiment can be combined with any of the other embodiments as appropriate.

### Embodiment 3

In this embodiment, another configuration example of the display portion described in Embodiment 1 will be described.

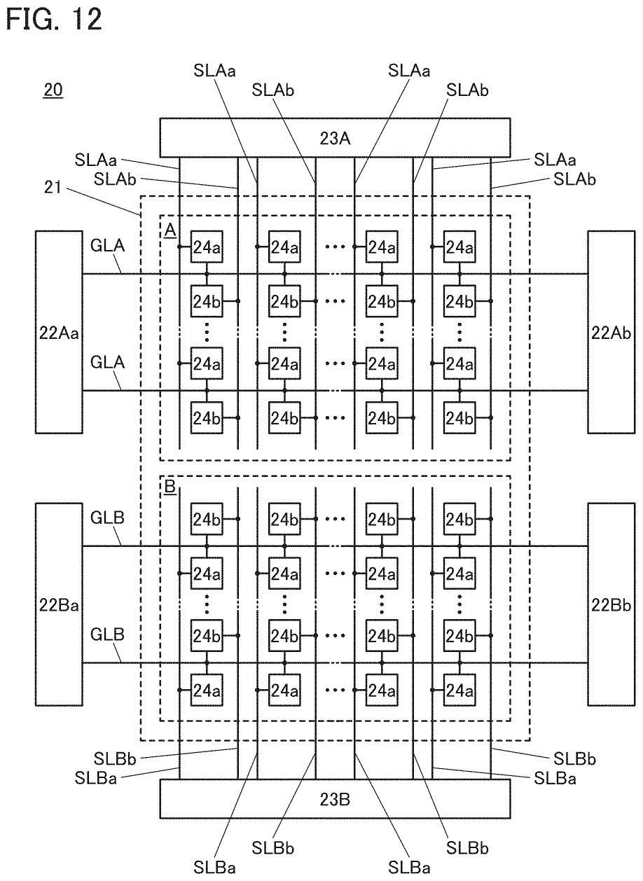

FIG. 12 illustrates a configuration example of the display portion 20 in which the pixel portion 21 is divided into a plurality of regions. Here, a configuration in which the pixel portion 21 is divided into two regions A and B will be described as an example. The regions A and B are connected to different driver circuits 22 and different driver circuits 23.

Since wirings GL and wirings SL are provided to intersect each other, the number of intersection points increases as the number of pixels 24 increases. Thus, parasitic capacitance formed by the wirings GL and the wirings SL increases, which may cause delay of image signals. Here, providing the driver circuit 23 supplying image signals to the region A and another driver circuit 23 supplying image signals to the region B separately from each other, as illustrated in FIG. 12, enables image signals to be supplied at high speed.

Note that, in FIG. 12, the wiring GL and the wiring SL connected to the pixels 24 in the region A are referred to as a wiring GLA and a wiring SLA, respectively. The wiring GL and the wiring SL connected to the pixels 24 in the region B are referred to as a wiring GLB and a wiring SLB, respectively. The driver circuit 22 connected to the wiring GLA and the driver circuit 22 connected to the wiring GLB are referred to as a driver circuit 22A and a driver circuit 22B, respectively. The driver circuit 23 connected to the wiring SLA and the driver circuit 23 connected to the wiring SLB are referred to as a driver circuit 23A and a driver circuit 23B, respectively.

Furthermore, in FIG. 12, one wiring GL is connected to two driver circuits 22. Specifically, the pixels 24 in the region A are connected to driver circuits 22Aa and 22Ab via the wirings GLA. The pixels 24 in the region B are connected to driver circuits 22Ba and 22Bb via the wirings GLB. In this case, timing when selection signals are output from the driver circuits 22Aa and 22Ab is synchronized, and timing when selection signals are output from the driver circuits 22Ba and 22Bb is synchronized. In this manner, the selection signals can be supplied from each end of the wiring GL, which enables the selection signals to be supplied at high speed.

Moreover, the number of wirings SL provided in the display portion 20 may be greater than the number of columns of the pixels 24. FIG. 12 shows a case in which the number of wirings SL connected to one driver circuit 23 is twice the number of columns of the pixels 24, as an example. Then, each of the pixels 24 in the region A is connected to a wiring SLAa or a wiring SLAb, and each of the pixels 24 in the region B is connected to a wiring SLBa or a wiring SLBb. Note that the pixels 24 connected to the wiring SLAa or the wiring SLBa are referred to as pixels 24a, and the pixels 24 connected to the wiring SLAb or the wiring SLBb are referred to as pixels 24b.

The pixels 24a and 24b are supplied with image signals from different wirings SL. Thus, the pixels 24a and 24b adjacent to each other can be supplied with selection signals at the same time. Accordingly, the scanning period of the wirings GL can be shortened, and thus the operation speed of the display portion 20 can be improved.

Note that the wiring GL to which selection signals are supplied at the same time can be shared. In FIG. 12, the wiring GL connected to adjacent pixels 24a and 24b are shared by these pixels. Consequently, the number of wirings GL can be reduced and the area of the display portion 20 can be smaller.

Although the case where the number of wirings SL connected to one driver circuit 23 is twice the number of columns of the pixels 24 is described above, the number of wirings SL may be triple the number of columns of the pixels 24 or greater. In that case, the number of wirings GL to which selection signals are supplied at the same time can further be increased, which improves the signal processing speed in the display portion 20.

This embodiment can be combined with any of the other embodiments as appropriate.

### Embodiment 4

In this embodiment, structure examples of a display device that can be used for the display system described in Embodiment 1 will be described.

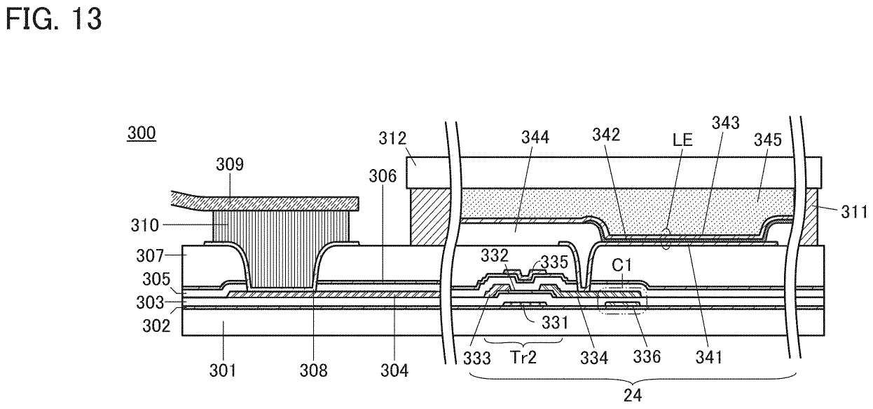

A structure example of a display device 300 which can be used as the display device 11 in FIG. 1 is illustrated in FIG. 13. The display device 300 has a function of displaying an image with the use of a light-emitting element.

The display device 300 includes an electrode 308, which is connected via an anisotropic conductive layer 310 to a terminal included in an FPC 309. The electrode 308 is also connected to a wiring 304 through an opening formed in insulating layers 307, 306, and 305. The electrode 308 is formed using the same material as that of an electrode layer 341.

The pixel 24 provided over a substrate 301 includes the transistor Tr2 (see FIG. 2B). The transistor Tr2 is provided over an insulating layer 302. The transistor Tr2 includes an electrode 331 provided over the insulating layer 302, and an insulating layer 303 is formed over the electrode 331. A semiconductor layer 332 is provided over the insulating layer 303. Electrodes 333 and 334 are provided over the semiconductor layer 332. The insulating layers 305 and 306 are provided over the electrodes 333 and 334. An electrode 335 is provided over the insulating layers 305 and 306. The electrodes 333 and 334 are formed using the same material as that of the wiring 304.

In the transistors Tr2, the electrode 331 serves as a gate electrode, the electrode 333 serves as one of a source electrode and a drain electrode, the electrode 334 serves as the other of the source electrode and the drain electrode, and the electrode 335 serves as a back gate electrode.

The transistor Tr2 has a bottom gate structure and includes a back gate as well, which can increase the on-state current of the transistor. In addition, the threshold voltage of the transistors can be controlled. The electrode 335 may not necessarily be formed in some cases to simplify the manufacturing process.

As a semiconductor material used in the transistor, a Group 14 element (e.g., silicon or germanium) or a metal oxide can be used, for example. Typically, a semiconductor containing silicon, a semiconductor containing gallium arsenide, a metal oxide containing indium, or the like can be used.

Silicon can be used as a semiconductor in which a channel of the transistor is formed, for example. In particular, amorphous silicon is preferably used as silicon. The use of amorphous silicon is good in terms of mass productivity since the transistors can be formed over a large substrate with a high yield.

Furthermore, silicon having crystallinity such as microcrystalline silicon, polycrystalline silicon, or single-crystal silicon can be used. In particular, polycrystalline silicon can be formed at a lower temperature than single-crystal silicon and has a higher field-effect mobility and a higher reliability than amorphous silicon.

As a semiconductor in which a channel of the transistor is formed, a metal oxide having a band gap wider than that of silicon can also be used. The use of a semiconductor material having a wider band gap and a lower carrier density than silicon is preferable because off-state current of the transistor can be reduced.

A transistor with a metal oxide whose band gap is larger than that of silicon has a low off-state current; therefore, charges stored in a capacitor that is series-connected to the transistor can be held for a long period. The use of such a transistor in pixels allows a driver circuit to stop while the gray level of an image displayed in each of the display regions is maintained. As a result, a display device with extremely low power consumption is obtained.

The metal oxide preferably includes, for example, a material referred to as an In-M-Zn-based oxide that contains at least indium, zinc, and M (a metal such as aluminum, titanium, gallium, germanium, yttrium, zirconium, lanthanum, cerium, tin, neodymium, or hafnium). In order to reduce variations in electrical characteristics of the transistors including the metal oxide, the oxide preferably contains a stabilizer in addition to the above.

As the stabilizer, gallium, tin, hafnium, aluminum, zirconium, or the like can be given, for example. As another stabilizer, lanthanoid such as lanthanum, cerium, praseodymium, neodymium, samarium, europium, gadolinium, terbium, dysprosium, holmium, erbium, thulium, ytterbium, or lutetium can be given.

As a metal oxide included in the semiconductor layer, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

Note that here, for example, an In—Ga—Zn-based oxide means an oxide containing In, Ga, and Zn as its main components and there is no limitation on the ratio of In:Ga:Zn. Furthermore, a metal element other than In, Ga, and Zn may also be contained.

The semiconductor layer and the conductive layer may include the same metal elements contained in the above oxides. The use of the same metal elements for the semiconductor layer and the conductive layer can reduce the manufacturing cost. For example, the use of metal oxide targets with the same metal composition can reduce the manufacturing cost. In addition, the same etching gas or the same etchant can be used in processing the semiconductor layer and the conductive layer. Note that even when the semiconductor layer and the conductive layer include the same metal elements, they have different compositions in some cases. For example, a metal element in a film is released during the manufacturing process of the transistor and the capacitor, which might result in different metal compositions.

The energy gap of the metal oxide included in the semiconductor layer is preferably greater than or equal to 2 eV, further preferably greater than or equal to 2.5 eV, and still further preferably greater than or equal to 3 eV. With the use of a metal oxide having such a wide energy gap, the off-state current of the transistor can be reduced.

In the case where the metal oxide contained in the semiconductor layer contains an In-M-Zn oxide, it is preferable that the atomic ratio of metal elements of a sputtering target used for forming a film of the In-M-Zn oxide satisfy In≥M and Zn≥M. As the atomic ratio of metal elements of such a sputtering target, In:M:Zn=1:1:1, In:M:Zn=1:1:1.2, In:M:Zn=3:1:2, In M:Zn=4:2:4.1 and the like are preferable. Note that the atomic ratio of metal elements in the formed semiconductor layer varies from the above atomic ratio of metal elements of the sputtering target within a range of ±40% as an error.

A metal oxide with a low carrier density is preferably used for the semiconductor layer. For example, the semiconductor layer is a metal oxide whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, yet further preferably lower than 1×10¹⁰/cm³, and higher than or equal to 1×10⁻⁹/cm³. Such a semiconductor layer has a low impurity concentration and a low density of defect states and thus has stable characteristics.

Note that without limitation to the compositions and materials described above, a material with an appropriate composition can be used depending on required semiconductor characteristics and electric characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

When silicon or carbon that is one of elements belonging to Group 14 is contained in the metal oxide contained in the semiconductor layer, oxygen vacancies are increased in the semiconductor layer, and the semiconductor layer might become n-type. Thus, the concentration of silicon or carbon (measured by secondary ion mass spectrometry) in the semiconductor layer is preferably lower than or equal to 2×10¹⁸ atoms/cm³, further preferably lower than or equal to 2×10¹⁷ atoms/cm³.

An alkali metal and an alkaline earth metal might generate carriers when bonded to a metal oxide, in which case the off-state current of the transistor might be increased. Therefore, the concentration of an alkali metal or alkaline earth metal of the semiconductor layer, which is measured by secondary ion mass spectrometry, is preferably lower than or equal to 1×10¹⁸ atoms/cm³, further preferably lower than or equal to 2×10¹⁶ atoms/cm³.

The metal oxide may have a non-single-crystal structure, for example. Non-single-crystal structures include a polycrystalline structure, a microcrystalline structure, and an amorphous structure, for example. Among the non-single-crystal structures, the amorphous structure has the highest density of defect states.

A metal oxide having an amorphous structure has disordered atomic arrangement and no crystalline component, for example. Alternatively, an oxide film having an amorphous structure has, for example, an absolutely amorphous structure and no crystal part.

Note that the metal oxide may be a mixed film including two or more of the following: a region having an amorphous structure, a region having a microcrystalline structure, a region having a polycrystalline structure, and a region having a single crystal structure. The mixed film has, for example, a single-layer structure or a stacked-layer structure including two or more of the above regions in some cases.

The semiconductor materials mentioned above can be used not only in the transistor Tr2 but also in the transistor Tr1 in FIG. 2B and the transistor Tr3 in FIG. 2C.

The display device 300 includes a capacitor C1. The capacitor C1 has a region where the electrode 334 and an electrode 336 overlap with each other with the insulating layer 303 positioned therebetween. The electrode 336 is formed using the same material as that of the electrode 331.

FIG. 13 illustrates an example of a display device including, as a display element, a light-emitting element such as an EL element. EL elements are classified into organic EL elements and inorganic EL elements.

In an organic EL element, by voltage application, electrons are injected from one electrode to the EL layer and holes are injected from the other electrode to the EL layer. Then, the carriers (electrons and holes) are recombined, and thus, a light-emitting organic compound is excited. The light-emitting organic compound returns to a ground state from the excited state, thereby emitting light. Owing to such a mechanism, this light-emitting element is referred to as a current-excitation light-emitting element. In addition to the light-emitting compound, the EL layer may further include any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like. The EL layer can be formed by an evaporation method (including a vacuum evaporation method), a transfer method, a printing method, an inkjet method, a coating method, or the like.

The inorganic EL elements are classified according to their element structures into a dispersion-type inorganic EL element and a thin-film inorganic EL element. A dispersion-type inorganic EL element includes a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is sandwiched between dielectric layers, which are further sandwiched between electrodes, and its light emission mechanism is localization type light emission that utilizes inner-shell electron transition of metal ions.

FIG. 13 illustrates an example where an organic EL element is used as the light-emitting element LE.

In FIG. 13, the light-emitting element LE is connected to the transistor Tr2 provided in the pixel 24. Although the light-emitting element LE is composed of a stack including the electrode layer 341, a light-emitting layer 342, and an electrode layer 343, one embodiment is not limited to this structure. The structure of the light-emitting element LE can be changed as appropriate in accordance with a direction in which light is extracted from the light-emitting element LE, or the like.

A partition wall 344 is formed using an organic insulating material or an inorganic insulating material. It is preferable that the partition wall 344 be formed using a photosensitive resin material, in particular, to have an opening over the electrode layer 341 so that a side surface of the opening slopes with continuous curvature.

The light-emitting layer 342 may be composed of a single layer or a stack of a plurality of layers.

A protective layer may be formed over the electrode layer 343 and the partition wall 344 in order to prevent entry of oxygen, hydrogen, moisture, carbon dioxide, or the like into the light-emitting element LE. For the protective layer, silicon nitride, silicon nitride oxide, aluminum oxide, aluminum nitride, aluminum oxynitride, aluminum nitride oxide, diamond like carbon (DLC), or the like can be used. In a space formed by the substrate 301, a substrate 312, and a sealant 311, a filler 345 is provided to seal the space. It is preferable that, in this manner, the light-emitting element be packaged (sealed) with a protective film (such as a laminate film or an ultraviolet curable resin film) or a cover member with high air-tightness and little degasification so that the light-emitting element is not exposed to the outside air.

As the filler 345, an ultraviolet curable resin or a thermosetting resin can be used as well as an inert gas such as nitrogen or argon; for example, polyvinyl chloride (PVC), an acrylic resin, polyimide, an epoxy resin, a silicone resin, polyvinyl butyral (PVB), ethylene vinyl acetate (EVA), or the like can be used. A drying agent may be contained in the filler 345.

A glass material such as a glass frit, or a resin that is curable at room temperature such as a two-component-mixture-type resin, a light curable resin, a thermosetting resin, and the like can be used for the sealant 311. A drying agent may be contained in the sealant 311.

In addition, if needed, an optical film such as a polarizing plate, a circularly polarizing plate (including an elliptically polarizing plate), a retardation plate (a quarter-wave plate or a half-wave plate), or a color filter may be provided as appropriate on a light-emitting surface of the light-emitting element. Furthermore, the polarizing plate or the circularly polarizing plate may be provided with an anti-reflection film. Anti-glare treatment by which reflected light can be diffused by projections and depressions on the surface so as to reduce the glare can be performed, for example.

When the light-emitting element has a microcavity structure, light with high color purity can be extracted. Furthermore, when a microcavity structure and a color filter are used in combination, the glare can be reduced and visibility of a display image can be increased.

The electrode layer 341 and the electrode layer 343 can be formed using a light-transmitting conductive material such as indium oxide containing tungsten oxide, indium zinc oxide containing tungsten oxide, indium oxide containing titanium oxide, indium tin oxide, indium tin oxide containing titanium oxide, indium zinc oxide, or indium tin oxide to which silicon oxide is added.

The electrode layer 341 and the electrode layer 343 can also be formed using one or more selected from metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); alloys thereof; or nitrides thereof.

Alternatively, a conductive composition containing a conductive high molecule (also referred to as a conductive polymer) can be used to form the electrode layer 341 and the electrode layer 343. As the conductive high molecule, a so-called π-electron conjugated conductive high molecule can be used. For example, polyaniline or a derivative thereof, polypyrrole or a derivative thereof, polythiophene or a derivative thereof, a copolymer of two or more of aniline, pyrrole, and thiophene or a derivative thereof can be given.

In order to extract light emitted from the light-emitting element LE to the outside, at least one of the electrode layer 341 and the electrode layer 343 is transparent. In accordance with how light is extracted, the structures of display devices are classified into a top emission structure, a bottom emission structure, and a dual emission structure. In the top emission structure, light is extracted from the substrate 312 side. In the bottom emission structure, light is extracted from the substrate 301 side. In the dual emission structure, light is extracted from both the substrate 312 side and the substrate 301 side. In the case where the display device 300 has the top emission structure, for example, the electrode layer 343 is transparent. In the case where the display device 300 has the bottom emission structure, for example, the electrode layer 341 is transparent. In the case where the display device 300 has the dual emission structure, for example, the electrode layer 341 and the electrode layer 343 are transparent.

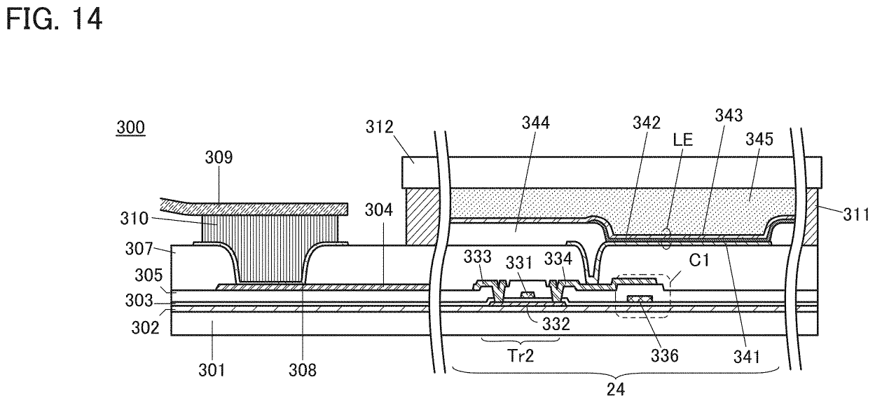

FIG. 14 is a cross-sectional view in which a top-gate transistor is provided as the transistor Tr2 in FIG. 13. In the transistor Tr2 in FIG. 14, the electrode 331 serves as a gate electrode, the electrode 333 serves as one of a source electrode and a drain electrode, and the electrode 334 serves as the other or the source electrode and the drain electrode.

The description of FIG. 13 can be referred to for the details of other components in FIG. 14.

In the case where a light-emitting element is used as the display element as illustrated in FIGS. 13 and 14, the display device 300 can be referred to as a light-emitting device. Although a light-emitting element is used as the display element in this embodiment, a liquid crystal element may be used as the display element as illustrated in FIG. 2C.

This embodiment can be combined with any of the other embodiments as appropriate.

### Embodiment 5

In this embodiment, a structure example of an OS transistor that can be used in the above embodiment will be described.

### Structure Example of Transistor

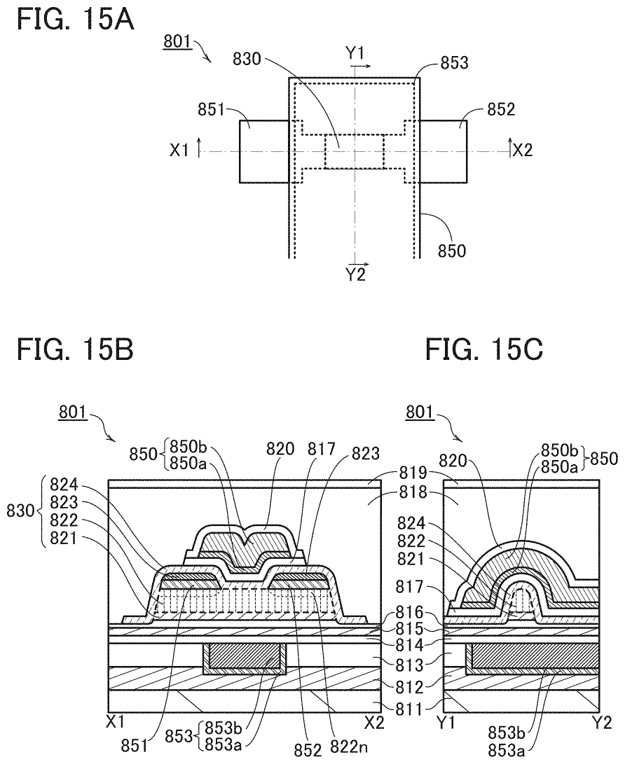

FIG. 15A is a top view illustrating a structure example of a transistor. FIG. 15B is a cross-sectional view taken along line X1-X2 in FIG. 15A. FIG. 15C is a cross-sectional view taken along line Y1-Y2 in FIG. 15A. In some cases, the direction of line X1-X2 is referred to as a channel length direction, and the direction of line Y1-Y2 is referred to as a channel width direction. FIG. 15B illustrates a cross-sectional structure of the transistor in the channel length direction, and FIG. 15C illustrates a cross-sectional structure of the transistor in the channel width direction. Note that to clarify the device structure, FIG. 15A does not illustrate some components.

The semiconductor device of one embodiment of the present invention includes insulating layers 812 to 820, metal oxide films 821 to 824, and conductive layers 850 to 853. A transistor 801 is formed over an insulating surface. FIGS. 15A to 15 illustrate the case where the transistor 801 is formed over an insulating layer 811. The transistor 801 is covered with the insulating layers 818 and 819.

Note that the insulating layers, the metal oxide films, the conductive layers, and the like that constitute the transistor 801 may each be a single film, or a stack including a plurality of films. They can be formed by any of a variety of deposition methods such as a sputtering method, a molecular beam epitaxy (MBE) method, a pulsed laser ablation (PLA) method, a CVD method, an atomic layer deposition (ALD) method, and the like. Note that examples of CVD methods include a plasma-enhanced CVD method, a thermal CVD method, and a metal organic CVD method.

The conductive layer 850 includes a region that serves as a gate electrode of the transistor 801. A conductive layer 851 and a conductive layer 852 include regions that serve as a source electrode and a drain electrode. The conductive layer 853 includes a region that serves as a back gate electrode. The insulating layer 17 includes a region that serves as a gate insulating layer on the gate electrode (front gate electrode) side, and an insulating layer that is a stack of the insulating layers 814 to 816 includes a region that serves as a gate insulating layer on the back gate electrode side. The insulating layer 818 serves as an interlayer insulating layer. The insulating layer 819 serves as a barrier layer.

The metal oxide films 821 to 824 are collectively referred to as an oxide layer 830. As illustrated in FIGS. 15B and 15C, the oxide layer 830 includes a region where the metal oxide film 821, the metal oxide film 822, and the metal oxide film 824 are stacked in this order. In addition, a pair of the metal oxide films 823 are positioned over the conductive layer 851 and the conductive layer 852. When the transistor 801 is on, a channel formation region is mainly formed in the metal oxide film 822 of the oxide layer 830.

The metal oxide film 824 covers the metal oxide films 821 to 823, the conductive layer 851, and the conductive layer 852. The insulating layer 817 is positioned between the metal oxide film 823 and the conductive layer 50. The conductive layers 851 and 852 each include a region that overlaps with the conductive layer 850 with the metal oxide film 823, the metal oxide film 824, and the insulating layer 817 positioned therebetween.

The conductive layers 851 and 852 are formed from a hard mask that is used in the formation of the metal oxide films 821 and 822. Thus, the conductive layers 851 and 852 do not include a region that is in contact with the side surfaces of the metal oxide films 821 and 822. For example, the metal oxide films 821 and 822 and the conductive layers 851 and 852 can be formed through the following steps. First, a conductive film is formed over a metal oxide film including a stack of two layers. The conductive film is processed (etched) into a desired shape so that a hard mask is formed. The hard mask is used to process the shape of the two-layered metal oxide film, forming the metal oxide films 821 and 822 that are stacked. Next, the hard mask is processed into a desired shape, forming the conductive layers 851 and 852.

Examples of insulating materials used for the insulating layers 811 to 818 include aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, and aluminum silicate. The insulating layers 811 to 818 are formed using a single-layer structure or a stacked-layer structure containing any of these insulating materials. The layers used for the insulating layers 811 to 818 may include a plurality of insulating materials.

In this specification and the like, oxynitride refers to a compound in which the oxygen content is higher than the nitrogen content, and nitride oxide refers to a compound in which the nitrogen content is higher than the oxygen content.

In order to suppress an increase in oxygen vacancies in the oxide layer 830, the insulating layers 816 to 818 preferably contain oxygen. More preferably, the insulating layers 816 to 818 are formed using an insulating film from which oxygen is released by heating (hereinafter such an insulating film is also referred to as an insulating film containing excess oxygen). When oxygen is supplied from the insulating film containing excess oxygen to the oxide layer 830, the oxygen vacancies in the oxide layer 830 can be compensated for. Thus, the reliability and electrical characteristics of the transistor 801 can be improved.

The insulating film containing excess oxygen is a film from which oxygen molecules at more than or equal to 1.0×10¹⁸ molecules/cm³ are released in thermal desorption spectroscopy (TDS) at a surface temperature of the film of higher than or equal to 100° C. and lower than or equal to 700° C., or higher than or equal to 100° C. and lower than or equal to 500° C. The amount of released oxygen molecules is preferably more than or equal to 3.0×10²⁰ atoms/cm³.

The insulating film containing excess oxygen can be formed by performing treatment for adding oxygen to an insulating film. The treatment for adding oxygen can be performed by heat treatment under an oxygen atmosphere, plasma treatment, or treatment using an ion implantation method, an ion doping method, or a plasma immersion ion implantation method, or the like. As a gas for adding oxygen, an oxygen gas of ¹⁶O₂, ¹⁸O₂, or the like, a nitrous oxide gas, an ozone gas, or the like can be used.

The concentration of hydrogen in the insulating layers 812 to 819 is preferably low in order to prevent an increase in the concentration of hydrogen in the oxide layer 830. In particular, the concentration of hydrogen in the insulating layers 813 to 818 is preferably low. Specifically, the concentration of hydrogen is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³.

The hydrogen concentration is measured by secondary ion mass spectrometry (SIMS). In the transistor 801, the oxide layer 830 is preferably surrounded by an insulating layer with oxygen and hydrogen barrier properties (hereinafter such an insulating layer is also referred to as a barrier layer). The use of such a structure prevents release of oxygen from the oxide layer 830 and entry of hydrogen into the oxide layer 830. Thus, the reliability and electrical characteristics of the transistor 801 can be improved.

For example, the insulating layer 819 serves as a barrier layer and at least one of the insulating layers 811, 812, and 814 serves as a barrier layer. The barrier layer can be formed using a material such as aluminum oxide, aluminum oxynitride, gallium oxide, gallium oxynitride, yttrium oxide, yttrium oxynitride, hafnium oxide, hafnium oxynitride, or silicon nitride.

A structure example of the insulating layers 811 to 819 is described. In this example, each of the insulating layers 811, 812, 815, and 819 serves as a barrier layer. The insulating layers 816 to 818 are oxide layers containing excess oxygen. The insulating layer 811 is formed using silicon nitride. The insulating layer 812 is formed using aluminum oxide. The insulating layer 813 is formed using silicon oxynitride. The insulating layers 814 to 816 serving as the gate insulating layers on the back gate electrode side are formed using a stack including silicon oxide, aluminum oxide, and silicon oxide. The insulating layer 817 serving as the gate insulating layer on the front gate side is formed using silicon oxynitride. The insulating layer 818 serving as the interlayer insulating layer is formed using silicon oxide. The insulating layer 819 is formed using aluminum oxide.

Examples of a conductive material used for the conductive layers 850 to 853 include a metal such as molybdenum, titanium, tantalum, tungsten, aluminum, copper, chromium, neodymium, or scandium; and a metal nitride containing any of the above metals as its component (e.g., tantalum nitride, titanium nitride, molybdenum nitride, or tungsten nitride). A conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added can be used.

A structure example of the conductive layers 850 to 853 is described. The conductive layer 850 is a single layer of tantalum nitride or tungsten. Alternatively, the conductive layer 850 is a stack including tantalum nitride, tantalum, and tantalum nitride. The conductive layer 851 is a single layer of tantalum nitride or a stack including tantalum nitride and tungsten. The structure of the conductive layer 852 is the same as that of the conductive layer 851. The conductive layer 853 is a single layer of tantalum nitride or a stack including tantalum nitride and tungsten.

In order to reduce the off-state current of the transistor 801, for example, the energy gap of the metal oxide film 822 is preferably large. The energy gap of the metal oxide film 822 is greater than or equal to 2.5 eV and less than or equal to 4.2 eV, preferably greater than or equal to 2.8 eV and less than or equal to 3.8 eV, further preferably greater than or equal to 3 eV and less than or equal to 3.5 eV.

The oxide layer 830 preferably exhibits crystallinity. At least the metal oxide film 822 preferably exhibits crystallinity. With the structure described above, the transistor 801 can have high reliability and favorable electrical characteristics.

As the oxide that can be used for the metal oxide film 822, for example, an In—Ga oxide, an In—Zn oxide, or an In-M-Zn oxide (M is Al, Ga, Y, or Sn) can be used. The metal oxide film 822 is not limited to the oxide layer containing indium. The metal oxide film 822 can be formed using a Zn—Sn oxide, a Ga—Sn oxide, or a Zn—Mg oxide, for example. The metal oxide films 821, 823, and 824 can be formed using an oxide that is similar to the oxide of the metal oxide film 822. In particular, each of the metal oxide films 821, 823 and 824 can be formed using a Ga oxide.

When an interface state is formed at the interface between the metal oxide film 822 and the metal oxide film 821, a channel formation region is formed also in the vicinity of the interface, which causes a change in the threshold voltage of the transistor 801. It is preferable that the metal oxide film 821 contain at least one of the metal elements contained in the metal oxide film 822 as its component. Accordingly, an interface state is unlikely to be formed at the interface between the metal oxide film 822 and the metal oxide film 821, and variations in the electrical characteristics of the transistor 801, such as the threshold voltage, can be reduced.

The metal oxide film 824 preferably contains at least one of the metal elements contained in the metal oxide film 822 as its component because interface scattering is unlikely to occur at the interface between the metal oxide film 822 and the metal oxide film 824, and carrier transfer is not inhibited. Thus, the field-effect mobility of the transistor 801 can be increased.

It is preferable that the metal oxide film 822 have the highest carrier mobility among the 822 that is apart from the insulating layers 816 and 817.

For example, in a metal oxide containing In such as an In-M-Zn oxide, carrier mobility can be increased by an increase in the In content. In the In-M-Zn oxide, the s orbital of heavy metal mainly contributes to carrier transfer, and when the indium content is increased, overlaps of the s orbitals of In atoms are increased; therefore, an oxide having a high content of indium has higher mobility than an oxide having a low content of indium. Therefore, an oxide having a high content of indium is used as the metal oxide film, so that carrier mobility can be increased.

Thus, for example, the metal oxide film 822 is formed using an In—Ga—Zn oxide, and the metal oxide films 821 and 823 are formed using a Ga oxide. For example, when the metal oxide films 821 to 823 are formed using an In-M-Zn oxide, the In content of the metal oxide film 822 is made higher than the In content of the metal oxide films 821 and 823. In the case where the In-M-Zn oxide is formed by a sputtering method, the In content can be changed by a change in the atomic ratio of metal elements of a target.

For example, it is preferable that the atomic ratio of metal elements of a target used for depositing the metal oxide film 822 be In:M:Zn=1:1:1, 3:1:2, or 4:2:4.1. For example, it is preferable that the atomic ratio of metal elements of a target used for depositing the metal oxide films 821 and 823 be In:M:Zn=1:3:2, or 1:3:4. The atomic ratio of an In-M-Zn oxide deposited using a target of In:M:Zn=4:2:4.1 is approximately In:M:Zn=4:2:3.

In order that the transistor 801 can have stable electrical characteristics, it is preferable to reduce the concentration of impurities in the oxide layer 830. In the metal oxide, hydrogen, nitrogen, carbon, silicon, and a metal element other than a main component are impurities. For example, hydrogen and nitrogen form donor states to increase the carrier density. In addition, silicon and carbon form impurity states in the metal oxide. The impurity states serve as traps and might cause the electrical characteristics of the transistor to deteriorate.

For example, the oxide layer 830 includes a region where the concentration of silicon is lower than or equal to 2×10¹⁸ atoms/cm³, preferably lower than or equal to 2×10¹⁷ atoms/cm³. The same applies to the concentration of carbon in the oxide layer 830.

The oxide layer 830 includes a region where the concentration of an alkali metal is lower than or equal to 1×10¹⁸ atoms/cm³, preferably lower than or equal to 2×10¹⁶ atoms/cm³. The same applies to the concentration of an alkaline earth metal in the oxide layer 830.

The oxide layer 830 includes a region where the concentration of hydrogen is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

The above concentrations of the impurities in the oxide layer 830 are measured by SIMS.

In the case where the metal oxide film 822 contains oxygen vacancies, donor states are formed by entry of hydrogen into sites of oxygen vacancies in some cases. The oxygen vacancy is a factor in decreasing the on-state current of the transistor 801. Note that sites of oxygen vacancies become more stable by entry of oxygen than by entry of hydrogen. Thus, by reducing oxygen vacancies in the metal oxide film 822, the on-state current of the transistor 801 can be increased in some cases. Consequently, preventing entry of hydrogen into sites of oxygen vacancies by a reduction in hydrogen in the metal oxide film 822 is effective in improving on-state current characteristics.

Hydrogen contained in a metal oxide reacts with oxygen bonded to a metal atom to be water, and thus causes an oxygen vacancy, in some cases. Due to entry of hydrogen into the oxygen vacancy, an electron serving as a carrier is generated in some cases. Furthermore, in some cases, bonding of part of hydrogen to oxygen bonded to a metal atom causes generation of an electron serving as a carrier. Thus, the transistor 801 is likely to be normally-on when the metal oxide film 822 contains hydrogen because the metal oxide film 822 includes a channel formation region. Accordingly, it is preferable that hydrogen in the metal oxide film 822 be reduced as much as possible.

Note that the metal oxide film 822 may have an n-type region 822n in a region in contact with the conductive layer 851 or the conductive layer 852. The region 822n is formed by a phenomenon in which oxygen in the metal oxide film 822 is extracted by the conductive layer 851 or 852, a phenomenon in which a conductive material in the conductive layer 851 or 852 is combined with an element in the metal oxide film 822, or the like. When the region 822n is formed, the contact resistance between the conductive layer 851 or 852 and the metal oxide film 822 can be reduced.

FIGS. 15A to 15C illustrate an example in which the oxide layer 830 has a four-layer structure; however, one embodiment of the present invention is not limited thereto. For example, the oxide layer 830 can have a three-layer structure without the metal oxide film 821 or without the metal oxide film 823. Alternatively, the oxide layer 830 may include one or more metal oxide films that are similar to the metal oxide films 821 to 824 at two or more of the following positions: between given layers in the oxide layer 830, over the oxide layer 830, and below the oxide layer 830.

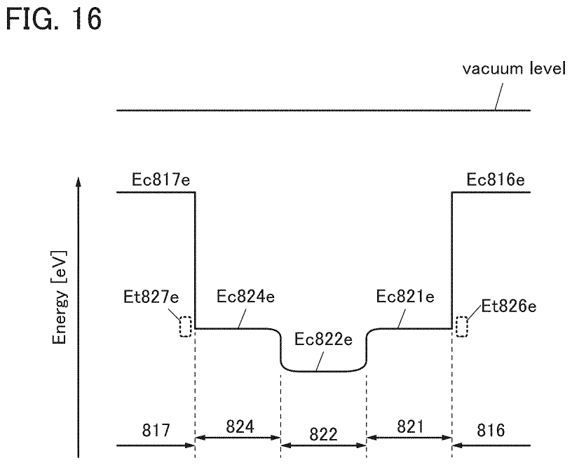

Effects of the stack including the metal oxide films 821, 822, and 824 are described with reference to FIG. 16. FIG. 16 is a schematic diagram showing the energy band structure of a channel formation region of the transistor 801.

In FIG. 16, Ec816e, Ec821e, Ec822e, Ec824e, and Ec817e indicate the energy of the conduction band minimums of the insulating layer 816, the metal oxide film 821, the metal oxide film 822, the metal oxide film 824, and the insulating layer 817, respectively.

Here, the energy difference between the vacuum level and the conduction band minimum (the difference is also referred to as electron affinity) corresponds to a value obtained by subtracting an energy gap from the energy difference between the vacuum level and the valence band maximum (the difference is also referred to as an ionization potential). The energy gap can be measured using a spectroscopic ellipsometer (UT-300 manufactured by HORIBA JOBIN YVON S.A.S.). The energy difference between the vacuum level and the valence band maximum can be measured using an ultraviolet photoelectron spectroscopy (UPS) device (VersaProbe manufactured by ULVAC-PHI, Inc.).

Since the insulating layers 816 and 817 are insulators, Ec816e and Ec817e are closer to the vacuum level than Ec821e, Ec822e, and Ec824e (i.e., the insulating layers 816 and 817 have lower electron affinities than the metal oxide films 821, 822, and 824).

The metal oxide film 822 has a higher electron affinity than the metal oxide films 821 and 824. For example, the difference in electron affinity between the metal oxide films 822 and 821 and the difference in electron affinity between the metal oxide films 822 and 824 are each greater than or equal to 0.07 eV and less than or equal to 1.3 eV, preferably greater than or equal to 0.1 eV and less than or equal to 0.7 eV, further preferably greater than or equal to 0.15 eV and less than or equal to 0.4 eV. Note that the electron affinity refers to an energy difference between the vacuum level and the conduction band minimum.

When voltage is applied to the gate electrode (the conductive layer 850) of the transistor 801, a channel is mainly formed in the metal oxide film 822 having the highest electron affinity among the metal oxide films 821, 822, and 824.

An indium gallium oxide has a small electron affinity and a high oxygen-blocking property. Therefore, the metal oxide film 824 preferably includes an indium gallium oxide. The gallium atomic ratio [Ga/(In+Ga)] is, for example, higher than or equal to 70%, preferably higher than or equal to 80%, further preferably higher than or equal to 90%.

In some cases, there is a mixed region of the metal oxide films 821 and 822 between the metal oxide films 821 and 822. Furthermore, in some cases, there is a mixed region of the metal oxide films 824 and 822 between the metal oxide films 824 and 822. Because the mixed region has a low interface state density, a region with a stack including the metal oxide films 821, 822, and 824 has a band structure where energy at each interface and in the vicinity of the interface is changed continuously (continuous junction).

Electrons transfer mainly through the metal oxide film 822 in the oxide layer 830 having such an energy band structure. Therefore, even when an interface state exists at the interface between the metal oxide film 821 and the insulating layer 816 or the interface between the metal oxide film 824 and the insulating layer 817, electron transfer in the oxide layer 830 is less likely to be inhibited and the on-state current of the transistor 801 can be increased.

Although trap states Et826e and Et827e due to impurities or defects might be formed in the vicinity of the interface between the metal oxide film 821 and the insulating layer 816 and the vicinity of the interface between the metal oxide film 824 and the insulating layer 817 as illustrated in FIG. 16, the metal oxide film 822 and the trap states Et826e and Et827e can be separated from each other owing to the existence of the metal oxide films 821 and 824.

Note that when a difference between Ec821e and Ec822e is small, an electron in the metal oxide film 822 might reach the trap state Et826e by passing over the difference in energy. Since the electron is trapped at the trap state Et826e, negative fixed charge is generated at the interface with the insulating film, causing the threshold voltage of the transistor to be shifted in a positive direction. The same applies to the case where a difference in energy between Ec822e and E824e is small.

Each of the difference in energy between Ec821e and Ec822e and the difference in energy between Ec824e and Ec822e is preferably greater than or equal to 0.1 eV, further preferably greater than or equal to 0.15 eV so that a change in the threshold voltage of the transistor 801 can be reduced and the transistor 801 can have favorable electrical characteristics.

Note that the transistor 801 does not necessarily include a back gate electrode.

### Example of Stacked-Layer Structure

Next, a structure of a semiconductor device in which an OS transistor and another transistor are stacked will be described.

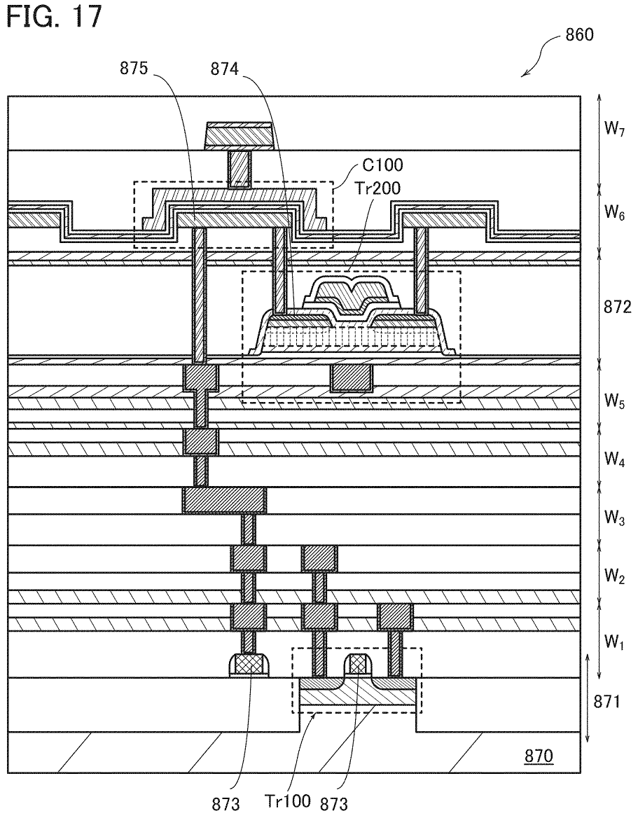

FIG. 17 illustrates an example of a stacked-layer structure of a semiconductor device 860 in which a transistor Tr100 that is a Si Transistor, a transistor Tr200 that is an OS transistor, and a capacitor C100 are stacked.

The semiconductor device 860 includes a stack including a CMOS layer 871, wiring layers W₁ to W₅, a transistor layer 872, and wiring layers W₆ and W₇.

The transistor Tr100 is provided in the CMOS layer 871. A channel formation region of the transistor Tr100 is provided in a single crystal silicon wafer 870. A gate electrode 873 of the transistor Tr100 is connected to one electrode 875 of the capacitor C100 through the wiring layers W₁ to W₅.

The transistor Tr200 is provided in the transistor layer 872. In FIG. 17, the transistor Tr200 has a structure similar to that of the transistor 801 (FIGS. 15A to 15C). An electrode 874 corresponding to one of a source and a drain of the transistor Tr200 is connected to the one electrode 875 of the capacitor C100. Note that in FIG. 17, the transistor Tr200 includes its back gate electrode in the wiring layer W₅. The capacitor C100 is formed in the wiring layer W₆.

The OS transistor and other components are stacked in this manner, whereby the area of the circuit can be reduced.

The above-described structure can be used for the semiconductor device 100 described in Embodiment 2 or the like. For example, the transistor Tr100, the transistor Tr200, and the capacitor C100 can be used as the transistor Tr11, the transistor Tr12, and the capacitor C11 in FIG. 9, respectively. It is also possible to use the transistor Tr100, the transistor Tr200, and the capacitor C100 as the transistor Tr21 or Tr24, the transistor Tr22, Tr23, Tr25, or Tr26, and the capacitor C21 or C22 in FIG. 10, respectively.

This embodiment can be combined with any of the other embodiments as appropriate.

### Embodiment 6

Described in this embodiment is a metal oxide that can be used in a transistor described in the above embodiment. In particular, the details of a metal oxide and a cloud-aligned composite (CAC)-OS will be described below.

A CAC-OS or a CAC metal oxide has a conducting function in a part of the material and has an insulating function in another part of the material; as a whole, the CAC-OS or the CAC metal oxide has a function of a semiconductor. In the case where the CAC-OS or the CAC metal oxide is used in a channel formation region of a transistor, the conducting function is to allow electrons (or holes) serving as carriers to flow, and the insulating function is to not allow electrons serving as carriers to flow. By the complementary action of the conducting function and the insulating function, the CAC-OS or the CAC metal oxide can have a switching function (on/off function). In the CAC-OS or CAC metal oxide, separation of the functions can maximize each function.

The CAC-OS or the CAC metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC metal oxide, the conductive regions and the insulating regions each have a size of more than or equal to 0.5 nm and less than or equal to 10 nm, preferably more than or equal to 0.5 nm and less than or equal to 3 nm and are dispersed in the material, in some cases.

The CAC-OS or the CAC metal oxide includes components having different bandgaps. For example, the CAC-OS or the CAC metal oxide includes a component having a wide gap due to the insulating region and a component having a narrow gap due to the conductive region. With such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or the CAC metal oxide is used in a channel formation region of a transistor, high current drive capability in the on state of the transistor, that is, a high on-state current and high field-effect mobility, can be obtained.

In other words, a CAC-OS or a CAC metal oxide can be called a matrix composite or a metal matrix composite.

The CAC-OS has, for example, a composition in which elements included in a metal oxide are unevenly distributed. Materials including unevenly distributed elements each have a size of greater than or equal to 0.5 nm and less than or equal to 10 nm, preferably greater than or equal to 1 nm and less than or equal to 2 nm, or a similar size. Note that in the following description of a metal oxide, a state in which one or more metal elements are unevenly distributed and regions including the metal element(s) are mixed is referred to as a mosaic pattern or a patch-like pattern. The regions each have a size of greater than or equal to 0.5 nm and less than or equal to 10 nm, preferably greater than or equal to 1 nm and less than or equal to 2 nm, or a similar size.

Note that a metal oxide preferably contains at least indium. In particular, indium and zinc are preferably contained. In addition, one or more selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, of the CAC-OS, an In—Ga—Zn oxide with the CAC composition (such an In—Ga—Zn oxide may be particularly referred to as CAC-IGZO) has a composition in which materials are separated into indium oxide (InO_{X1}, where X1 is a real number greater than 0) or indium zinc oxide (In_{X2}Zn_{Y2}O_{Z2}, where X2, Y2, and Z2 are real numbers greater than 0), and gallium oxide (GaO_{X3}, where X3 is a real number greater than 0), gallium zinc oxide (Ga_{X4}Zn_{Y4}O_{Z4}, where X4, Y4, and Z4 are real numbers greater than 0), or the like, and a mosaic pattern is formed. Then, InO_{X1} or In_{X2}Zn_{Y2}O_{Z2} forming the mosaic pattern is evenly distributed in the film. This composition is also referred to as a cloud-like composition.

That is, the CAC-OS is a composite metal oxide with a composition in which a region including GaO_{X3} as a main component and a region including In_{X2}Zn_{Y2}O_{Z2} or InO_{X1} as a main component are mixed. Note that in this specification, for example, when the atomic ratio of In to an element M in a first region is greater than the atomic ratio of In to an element M in a second region, the first region has higher In concentration than the second region.

Note that a compound including In, Ga, Zn, and O is also known as IGZO. Typical examples of IGZO include a crystalline compound represented by InGaO₃(ZnO)ₘ₁ (m1 is a natural number) and a crystalline compound represented by In₍₁₊ₓ₀₎Ga₍₁₋ₓ₀₎O₃(ZnO)ₘ₀ (−1≤x0≤1; m0 is a given number).

The above crystalline compounds have a single crystal structure, a polycrystalline structure, or a c-axis-aligned crystal (CAAC) structure. Note that the CAAC structure is a crystal structure in which a plurality of IGZO nanocrystals have c-axis alignment and are connected in the a-b plane direction without alignment.

On the other hand, the CAC-OS relates to the material composition of a metal oxide. In a material composition of a CAC-OS including In, Ga, Zn, and O, nanoparticle regions including Ga as a main component are observed in part of the CAC-OS and nanoparticle regions including In as a main component are observed in part thereof. These nanoparticle regions are randomly dispersed to form a mosaic pattern. Therefore, the crystal structure is a secondary element for the CAC-OS.

Note that in the CAC-OS, a stacked-layer structure including two or more films with different atomic ratios is not included. For example, a two-layer structure of a film including In as a main component and a film including Ga as a main component is not included.

A boundary between the region including GaO_{X3} as a main component and the region including In_{X2}Zn_{Y2}O_{Z2} or InO_{X1} as a main component is not clearly observed in some cases. In the case where one or more of aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions including the selected metal element(s) as a main component(s) are observed in part of the CAC-OS and nanoparticle regions including In as a main component are observed in part thereof, and these nanoparticle regions are randomly dispersed to form a mosaic pattern in the CAC-OS.

The CAC-OS can be formed by a sputtering method under conditions where a substrate is not heated intentionally, for example. In the case where the CAC-OS is formed by a sputtering method, one or more selected from an inert gas (typically, argon), an oxygen gas, and a nitrogen gas may be used as a deposition gas. The ratio of the flow rate of an oxygen gas to the total flow rate of the deposition gas at the time of deposition is preferably as low as possible, and for example, the flow ratio of an oxygen gas is preferably higher than or equal to 0% and less than 30%, further preferably higher than or equal to 0% and less than or equal to 10%.

The CAC-OS is characterized in that no clear peak is observed in measurement using θ/2θ scan by an out-of-plane method, which is an X-ray diffraction (XRD) measurement method. That is, X-ray diffraction shows no alignment in the a-b plane direction and the c-axis direction in a measured region.

In an electron diffraction pattern of the CAC-OS which is obtained by irradiation with an electron beam with a probe diameter of 1 nm (also referred to as a nanometer-sized electron beam), a ring-like region with high luminance and a plurality of bright spots in the ring-like region are observed. Therefore, the electron diffraction pattern indicates that the crystal structure of the CAC-OS includes a nanocrystal (nc) structure with no alignment in plan-view and cross-sectional directions.

For example, an energy dispersive X-ray spectroscopy (EDX) mapping image confirms that an In—Ga—Zn oxide with the CAC composition has a structure in which a region including GaO_{X3} as a main component and a region including In_{X2}Zn_{Y2}O_{Z2} or InO_{X1} as a main component are unevenly distributed and mixed.

The CAC-OS has a structure different from that of an IGZO compound in which metal elements are evenly distributed, and has characteristics different from those of the IGZO compound. That is, in the CAC-OS, regions including GaO_{X3} or the like as a main component and regions including In_{X2}Zn_{Y2}O_{Z2} or InO_{X1} as a main component are separated to form a mosaic pattern.

The conductivity of a region including In_{X2}Zn_{Y2}O_{Z2} or InO_{X1} as a main component is higher than that of a region including GaO_{X3} or the like as a main component. In other words, when carriers flow through regions including In_{X2}Zn_{Y2}O_{Z2} or InO_{X1} as a main component, the conductivity of an oxide semiconductor is exhibited. Accordingly, when regions including In_{X2}Zn_{Y2}O_{Z2} or InO_{X1} as a main component are distributed in an oxide semiconductor like a cloud, high field-effect mobility (μ) can be achieved.

In contrast, the insulating property of a region including GaO_{X3} or the like as a main component is higher than that of a region including In_{X2}Zn_{Y2}O_{Z2} or InO_{X1} as a main component. In other words, when regions including GaO_{X3} or the like as a main component are distributed in an oxide semiconductor, leakage current can be suppressed and favorable switching operation can be achieved.

Accordingly, when a CAC-OS is used for a semiconductor element, the insulating property derived from GaO_{X3} or the like and the conductivity derived from In_{X2}Zn_{Y2}O_{Z2} or InO_{X1} complement each other, whereby high on-state current (Iₒₙ) and high field-effect mobility (μ) can be achieved.

A semiconductor element including a CAC-OS has high reliability. Thus, the CAC-OS is suitably used in a variety of semiconductor devices.

This embodiment can be combined with any of the other embodiments as appropriate.

### Embodiment 7

In this embodiment, an electronic device of one embodiment of the present invention will be described with reference to drawings.

The display system described in any of the above embodiments can be provided in any of the examples of the electronic device described below. Thus, an electronic device which can display a high-quality image can be provided.

The display portion of the electronic device of one embodiment of the present invention can display an image with a resolution of, for example, full high definition, 2K, 4K, 8K, 16K, or more. As a screen size of the display portion, the diagonal size can be greater than or equal to 20 inches, greater than or equal to 30 inches, greater than or equal to 50 inches, greater than or equal to 60 inches, or greater than or equal to 70 inches.

Examples of electronic devices include electronic devices having relatively large screens such as a television set, a desktop or laptop personal computer, a monitor of a computer, digital signage, and a large game machine (e.g., a pachinko machine); a digital camera; a digital video camera; a digital photo frame; a mobile phone; a portable game console; a portable information terminal; an audio reproducing device; and the like.

The electronic device of one embodiment of the present invention can be incorporated along a curved inside/outside wall surface of a house or a building or a curved interior/exterior surface of a car.

The electronic device of one embodiment of the present invention may include an antenna. When a signal is received by the antenna, the electronic device can display an image, data, or the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, chemical substance, sound, time, hardness, electric field, electric current, voltage, electric power, radiation, flow rate, humidity, gradient, oscillation, odor, or infrared rays).

The electronic device of one embodiment of the present invention can have a variety of functions such as a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

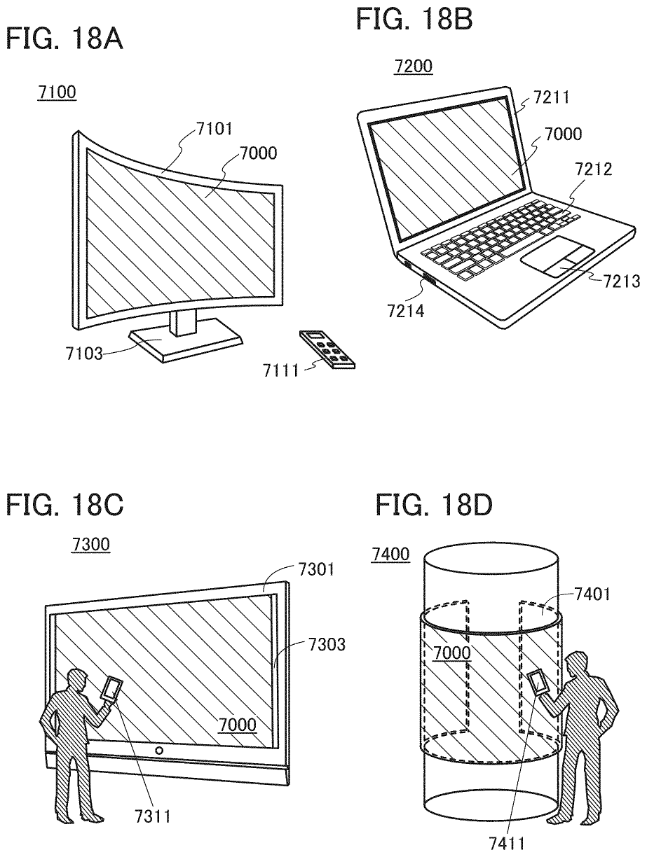

FIG. 18A illustrates an example of a television device. In a television device 7100, a display portion 7000 is incorporated in a housing 7101. In addition, here, the housing 7101 is supported by a stand 7103.

The display system or semiconductor device of one embodiment of the present invention can be used in the display portion 7000.

The television device 7100 illustrated in FIG. 18A can be operated with an operation switch provided in the housing 7101 or a separate remote controller 7111. Furthermore, the display portion 7000 may include a touch sensor. The television device 7100 can be operated by touching the display portion 7000 with a finger or the like. Furthermore, the remote controller 7111 may be provided with a display portion for displaying data outputted from the remote controller 7111. With operation keys or a touch panel of the remote controller 7111, channels and volume can be controlled and images displayed on the display portion 7000 can be controlled.

Note that the television device 7100 is provided with a receiver, a modem, and the like. With use of the receiver, general television broadcasting can be received. When the television device is connected to a communication network with or without wires via the modem, one-way (from a transmitter to a receiver) or two-way (between a transmitter and a receiver or between receivers) data communication can be performed.

FIG. 18B illustrates a laptop personal computer 7200. The laptop personal computer 7200 includes a housing 7211, a keyboard 7212, a pointing device 7213, an external connection port 7214, and the like. In the housing 7211, the display portion 7000 is incorporated.

The display system or semiconductor device of one embodiment of the present invention can be used in the display portion 7000.

FIGS. 18C and 18D illustrate examples of digital signages.

A digital signage 7300 illustrated in FIG. 18C includes a housing 7301, the display portion 7000, a speaker 7303, and the like. Also, the digital signage can include an LED lamp, operation keys (including a power switch or an operation switch), a connection terminal, a variety of sensors, a microphone, and the like.

FIG. 18D illustrates a digital signage 7400 mounted on a cylindrical pillar 7401. The digital signage 7400 includes the display portion 7000 provided along a curved surface of the pillar 7401.

The display system or semiconductor device of one embodiment of the present invention can be used for each of the display portions 7000 illustrated in FIGS. 18C and 18D.

A larger area of the display portion 7000 can provide more information at a time. In addition, the larger display portion 7000 attracts more attention, so that the effectiveness of the advertisement can be increased, for example.

It is preferable to use a touch panel in the display portion 7000 because a device with such a structure does not just display a still or moving image, but can be operated by users intuitively. Alternatively, in the case where the display device of one embodiment of the present invention is used for providing information such as route information or traffic information, usability can be enhanced by intuitive operation.

Furthermore, as illustrated in FIGS. 18C and 18D, it is preferable that the digital signage 7300 or the digital signage 7400 work with an information terminal 7311 or an information terminal 7411 such as a smartphone a user has through wireless communication. For example, information of an advertisement displayed on the display portion 7000 can be displayed on a screen of the information terminal 7311 or 7411. Moreover, by operation of the information terminal 7311 or 7411, a displayed image on the display portion 7000 can be switched.

Furthermore, it is possible to make the digital signage 7300 or 7400 execute a game with use of the screen of the information terminal 7311 or 7411 as an operation means (controller). Thus, an unspecified number of people can join in and enjoy the game concurrently.

This embodiment can be combined with any of the other embodiments as appropriate.

### REFERENCE NUMERALS

10: display system, 11: display device, 20: display portion, 21: pixel portion, 22: driver circuit, 23: driver circuit, 24: pixel, 25: region, 30: signal generation portion, 31: reception portion, 32: processing portion, 33: processing portion, 34: processing portion, 40: arithmetic portion, 41: database, 42: processing portion, 43: processing portion, 100: semiconductor device, 110: memory circuit, 120: reference memory circuit, 130: circuit, 140: circuit, 150: current supply circuit, 300: display device, 301: substrate, 302: insulating layer, 303: insulating layer, 304: wiring, 305: insulating layer, 306: insulating layer, 307: insulating layer, 308: electrode, 309: FPC, 310: anisotropic conductive layer, 311: sealant, 312: substrate, 331: electrode, 332: semiconductor layer, 333: electrode, 334: electrode, 335: electrode, 336: electrode, 341: electrode layer, 342: light-emitting layer, 343: electrode layer, 344: partition wall, 345: filler, 801: transistor, 811: insulating layer, 812: insulating layer, 813: insulating layer, 814: insulating layer, 815: insulating layer, 816: insulating layer, 817: insulating layer, 818: insulating layer, 819: insulating layer, 820: insulating layer, 821: metal oxide film, 822: metal oxide film, 823: metal oxide film, 824: metal oxide film, 830: oxide layer, 850: conductive layer, 851: conductive layer, 852: conductive layer, 853: conductive layer, 860: semiconductor device, 870: single crystal silicon wafer, 871: CMOS layer, 872: transistor layer, 873: gate electrode, 874: electrode, 875: electrode, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, and 7411: information terminal.

This application is based on Japanese Patent Application Serial No. 2017-025614 filed with Japan Patent Office on Feb. 15, 2017, the entire contents of which are hereby incorporated by reference.

1. A semiconductor device comprising:
a database;
a first processing portion; and
a second processing portion,
wherein the database is capable of storing first data and second data,
wherein the first data corresponds to an image displayed on a display portion
comprising a pixel portion divided into N×M regions,
wherein N and M are each an integer of 2 or greater,
wherein the second data corresponds to an image intended to be displayed on the display portion,
wherein the first processing portion is capable of dividing the first data into N×M pieces of third data,
wherein the first processing portion is capable of dividing the second data into N×M pieces of fourth data,
wherein the second processing portion comprises a first neural network capable of learning,
wherein the first neural network is capable of learning with use of the third data and the fourth data, and
wherein N×M weight coefficients obtained through the learning are output to a signal generation portion.

2. (canceled)

3. The semiconductor device according to claim 1, wherein the first data is obtained through capturing an image displayed on the display portion.

4. A display system comprising:
an arithmetic portion comprising the semiconductor device according to claim 1; and
the signal generation portion,
wherein the signal generation portion comprises:
a reception portion;
a third processing portion;
a fourth processing portion; and
a fifth processing portion,
wherein the reception portion is capable of receiving image data,
wherein the third processing portion is capable of dividing the image data into N×M pieces of fifth data,
wherein the fourth processing portion is capable of correcting the N×M pieces of the fifth data,
wherein the fifth processing portion is capable of generating an image signal by uniting the N×M pieces of the fifth data which are corrected,
wherein the fourth processing portion comprises a second neural network capable of inference,
wherein the second neural network is capable of correcting the fifth data through inference, and
wherein the N×M weight coefficients are stored in the second neural network.

5. The display system according to claim 4,
wherein the second neural network comprises a product-sum operation element,
wherein the product-sum operation element comprises a memory circuit comprising a first transistor, a second transistor, and a capacitor,
wherein one of a source and a drain of the first transistor is electrically connected to a gate of the second transistor and the capacitor, and
wherein the first transistor comprises a metal oxide in a channel formation region.

6. The display system according to claim 4,
wherein the pixel portion comprises a plurality of pixels, and
wherein each of the plurality of pixels comprises a light-emitting element.

7. A semiconductor device comprising:
a database;
a first processing portion; and
a second processing portion,
wherein the database is capable of storing first data and second data,
wherein the first data corresponds to an image displayed on a display portion comprising a pixel portion divided into N×M regions,
wherein N and M are each an integer of 2 or greater,
wherein the second data corresponds to an image intended to be displayed on the display portion,
wherein the first processing portion is capable of dividing the first data into N×M pieces of third data,
wherein the first processing portion is capable of dividing the second data into N×M pieces of fourth data,
wherein the second processing portion comprises a first neural network capable of learning,
wherein the first neural network is capable of learning with use of the third data and the fourth data,
wherein N×M weight coefficients obtained through the learning are output to a signal generation portion, and
wherein the first neural network is capable of learning with use of the third data as learning data and the fourth data as teacher data.

8. The semiconductor device according to claim 7, wherein the first data is obtained through capturing an image displayed on the display portion.

9. A display system comprising:
an arithmetic portion comprising the semiconductor device according to claim 7; and
the signal generation portion,
wherein the signal generation portion comprises:
a reception portion;
a third processing portion;
a fourth processing portion; and
a fifth processing portion,
wherein the reception portion is capable of receiving image data,
wherein the third processing portion is capable of dividing the image data into N×M pieces of fifth data,
wherein the fourth processing portion is capable of correcting the N×M pieces of the fifth data,
wherein the fifth processing portion is capable of generating an image signal by uniting the N×M pieces of the fifth data which are corrected,
wherein the fourth processing portion comprises a second neural network capable of inference,
wherein the second neural network is capable of correcting the fifth data through inference, and
wherein the N×M weight coefficients are stored in the second neural network.

10. The display system according to claim 9,
wherein the second neural network comprises a product-sum operation element,
wherein the product-sum operation element comprises a memory circuit comprising a first transistor, a second transistor, and a capacitor,
wherein one of a source and a drain of the first transistor is electrically connected to a gate of the second transistor and the capacitor, and
wherein the first transistor comprises a metal oxide in a channel formation region.

11. The display system according to claim 9,
wherein the pixel portion comprises a plurality of pixels, and
wherein each of the plurality of pixels comprises a light-emitting element.
